(19) United States
(12) Patent Application Publication
(10) Pub. No.: US 2026/0011293 A1
(43) Pub. Date: Jan. 8, 2026

(54) ELECTRONIC DEVICE

(71) Applicant: Samsung Display Co., LTD., Yongin-si (KR)

(72) Inventors: Yerim SON, Yongin-si (KR); YOOMIN KO, Yongin-si (KR); SUNHO KIM, Yongin-si (KR); JUCHAN PARK, Yongin-si (KR)

(21) Appl. No.: 19/244,633

(22) Filed: Jun. 20, 2025

(30) Foreign Application Priority Data
Jul. 2, 2024 (KR) 10-2024-0086550

(51) Int. Cl. G09G 3/32; H10H 29/37; H10H 29/49

(52) U.S. Cl. CPC G09G 3/32; H10H 29/37; H10H 29/49; G09G 2320/0257; G09G 2330/021

(57) ABSTRACT

An electronic device includes a drive element layer including a pixel driver, a light emitting element including a first electrode, an intermediate layer disposed on the first electrode and including at least an emissive layer, and a second electrode disposed on the intermediate layer, a pixel defining layer having an opening defined therein which exposes at least a portion of the first electrode, a connecting electrode disposed on the pixel defining layer and electrically connected with the pixel driver and the second electrode, a connecting line disposed between the pixel driver and the pixel defining layer and electrically connected with the pixel driver and the connecting electrode, and a separator disposed on the pixel defining layer. The second electrode is contacting the connecting electrode in each of a first contact area adjacent to the separator and a second contact area adjacent to a side surface of the connecting line.

This application claims priority to Korean Patent Application No. 10-2024-0086550, filed on Jul. 2, 2024, and all the benefits accruing therefrom under 35 U.S.C. § 119, the content of which in its entirety is herein incorporated by reference.

### BACKGROUND

Embodiments of the present disclosure described herein relate to an electronic device with improved contact reliability.

Multimedia electronic devices, such as a television, a mobile phone, a tablet computer, a car navigation unit, a game machine, and the like, include a display panel for displaying an image. A display panel includes light emitting elements and circuits for driving the light emitting elements. Based on voltages applied from the circuits, the light emitting elements included in the display panel emit light and generate an image. In order to improve the reliability of the display panel, studies on the connection between the light emitting elements and the circuits are being conducted.

### SUMMARY

Embodiments of the present disclosure provide an electronic device with improved contact reliability.

According to an embodiment, an electronic device includes a drive element layer including a pixel driver, a light emitting element that is disposed on the drive element layer and that includes a first electrode, an intermediate layer disposed on the first electrode and including at least an emissive layer, and a second electrode disposed on the intermediate layer, a pixel defining layer disposed on the drive element layer, wherein an opening defined in the pixel defining layer exposes at least a portion of the first electrode, a connecting electrode disposed on the pixel defining layer and electrically connected with the pixel driver and the second electrode, a connecting line disposed between the pixel driver and the pixel defining layer and electrically connected with the pixel driver and the connecting electrode, and a separator disposed on the pixel defining layer. The second electrode is in contact with the connecting electrode in each of a first contact area adjacent to the separator and a second contact area adjacent to a side surface of the connecting line.

A lower surface of the second electrode may be in contact with an upper surface of the connecting electrode in the first contact area.

A tip portion may be defined on at least a portion of an edge of the connecting line, and the second contact area may be adjacent to the tip portion.

The connecting line may include a first layer, a second layer disposed on the first layer, and a third layer disposed on the second layer, and a side surface of each of the first layer and the third layer may protrude relative to a side surface of the second layer.

An end portion of the connecting electrode may be connected to the side surface of the second layer, and an end portion of the second electrode may be in contact with the end portion of the connecting electrode connected to the side surface of the second layer.

Each of an opposite end portion of the connecting electrode and an opposite end portion of the second electrode may be disposed on an upper surface of the first layer.

The end portion of the connecting electrode may be in contact with the side surface of the second layer.

The electronic device may further include a capping pattern disposed between the connecting line and the connecting electrode. An end portion of the capping pattern may be in contact with the side surface of the second layer, and an opposite end portion of the capping pattern may be disposed on the upper surface of the first layer. The end portion of the second electrode may be in contact with the end portion of the capping pattern brought into contact with the side surface of the second layer.

A first through hole defined in the pixel defining layer may expose the tip portion defined on at least the portion of the edge of the connecting line.

The drive element layer of the electronic device may further include an intermediate insulating layer that is disposed under the pixel defining layer and that covers a portion of the connecting line, and a second through hole defined in the intermediate insulating layer may expose the tip portion defined on at least the portion of the edge of the connecting line.

The drive element layer of the electronic device may further include a lower insulating layer disposed between the pixel driver and the connecting line, and the connecting line may be connected to the pixel driver through a contact hole that penetrates the lower insulating layer.

The connecting electrode may have a ring shape and surround the opening, and the first contact area may have a ring shape and surround at least a portion of the opening.

The connecting electrode may include a first edge and a second edge that surrounds the first edge, and the second edge may overlap the separator.

A portion of the connecting electrode may be covered by the separator.

The light emitting element may include a plurality of light emitting elements, the pixel driver may include a plurality of pixel drivers, and the connecting electrode may include a plurality of connecting electrodes. The plurality of connecting electrodes may electrically connect the plurality of light emitting elements and the plurality of pixel drivers, respectively. A gap between connecting electrodes adjacent to each other among the plurality of connecting electrodes may overlap the separator.

The intermediate layer may further include a functional layer. The functional layer may include a first intermediate functional layer disposed on the first electrode and a second intermediate functional layer disposed on the emissive layer, and the emissive layer may be disposed between the first intermediate functional layer and the second intermediate functional layer.

The electronic device may further include a first dummy layer that is disposed on the separator and that includes a same material as the functional layer and a second dummy layer that is disposed on the first dummy layer and that includes a same material as the second electrode.

According to an embodiment, an electronic device includes a drive element layer including a pixel driver, a light emitting element that is disposed on the drive element layer and that includes a first electrode, an intermediate layer disposed on the first electrode and including at least an emissive layer, and a second electrode disposed on the intermediate layer, a pixel defining layer that is disposed on the drive element layer, wherein an opening defined in the pixel defining layer exposes at least a portion of the first electrode, a connecting electrode disposed on the pixel defining layer and electrically connected with the pixel driver and the second electrode, a connecting line disposed between the pixel driver and the pixel defining layer and electrically connected with the pixel driver and the connecting electrode, and a separator disposed on the pixel defining layer. An edge of the connecting electrode overlaps the separator. A tip portion is defined on at least a portion of an edge of the connecting line, and the connecting electrode is connected to at least the portion of the edge of the connecting line where the tip portion is defined.

The second electrode may be in contact with the connecting electrode in each of a first contact area adjacent to the separator and a second contact area adjacent to the tip portion of the connecting line.

The connecting line may include a first layer, a second layer disposed on the first layer, and a third layer disposed on the second layer. A side surface of each of the first layer and the third layer may protrude relative to a side surface of the second layer. An end portion of the connecting electrode may be connected to the side surface of the second layer, and an end portion of the second electrode may be in contact with the end portion of the connecting electrode connected to the side surface of the second layer.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to an embodiment of the present disclosure.

FIG. 2A is an equivalent circuit diagram of a pixel according to an embodiment of the present disclosure.

FIG. 2B is an equivalent circuit diagram of a pixel according to an embodiment of the present disclosure.

FIG. 2C is an equivalent circuit diagram of a pixel according to an embodiment of the present disclosure.

FIG. 3A is a schematic plan view illustrating a display panel according to an embodiment of the present disclosure.

FIG. 3B is a schematic plan view illustrating the display panel according to an embodiment of the present disclosure.

FIG. 4A is an enlarged plan view of a partial area of the display panel according to an embodiment of the present disclosure.

FIG. 4B is an enlarged plan view of a partial area of the display panel according to an embodiment of the present disclosure.

FIG. 4C is an enlarged plan view of a partial area of the display panel according to an embodiment of the present disclosure.

FIG. 4D is an enlarged plan view of a partial area of the display panel according to an embodiment of the present disclosure.

FIG. 5 is a sectional view of the display panel according to an embodiment of the present disclosure.

FIG. 6 is an enlarged sectional view of a partial area of the display panel according to an embodiment of the present disclosure.

FIG. 7 is an enlarged sectional view of a partial area of the display panel according to an embodiment of the present disclosure.

FIG. 8 is a graph depicting luminance versus first power supply voltage in an embodiment of the present disclosure and a comparative example.

FIGS. 9A and 9B illustrate images related to UHAST evaluation according to a comparative example.

FIGS. 10A and 10B illustrate images related to UHAST evaluation according to an embodiment of the present disclosure.

FIG. 11 is a sectional view of a display panel according to an embodiment of the present disclosure.

FIG. 12 is an enlarged sectional view of a partial area of the display panel according to an embodiment of the present disclosure.

### DETAILED DESCRIPTION

In this specification, when a component (or, an area, a layer, a part, or the like) is referred to as being “on”, “connected to” or “coupled to” another component, this means that the component may be directly on, connected to, or coupled to the other component or a third component may be present therebetween.

Identical reference numerals refer to identical components. In the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms as used herein may distinguish one component from other components. For example, without departing the scope of the present disclosure, a first component may be referred to as a second component, and similarly, the second component may also be referred to as the first component. The terms of a singular form may include plural forms unless otherwise specified.

Terms such as, for example, “below”, “under”, “above”, and “over” are used to describe a relationship between components illustrated in the drawings. The terms are relative concepts and are described based on directions illustrated in the drawing.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially the same shape” means approximately or actually the same shape. The term “substantially correspond to” means approximately or actually correspond to.

The term “adjacent” herein may refer to elements which are relatively close to each other (e.g., within a target distance). In some other cases, the term “adjacent” herein may refer to elements which are in contact with each other.

It should be understood that terms such as, for example, “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

The terms “part” and “unit” mean a software component or a hardware component that performs a specific function. The hardware component may include, for example, a field-programmable gate array (FPGA) or an application-specific integrated circuit (ASIC). The software component may refer to executable code and/or data used by executable code in an addressable storage medium. Thus, software components may be, for example, object-oriented software components, class components, and working components, and may include processes, functions, properties, procedures, subroutines, program code segments, drivers, firmware, micro-codes, circuits, data, databases, data structures, tables, arrays or variables.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

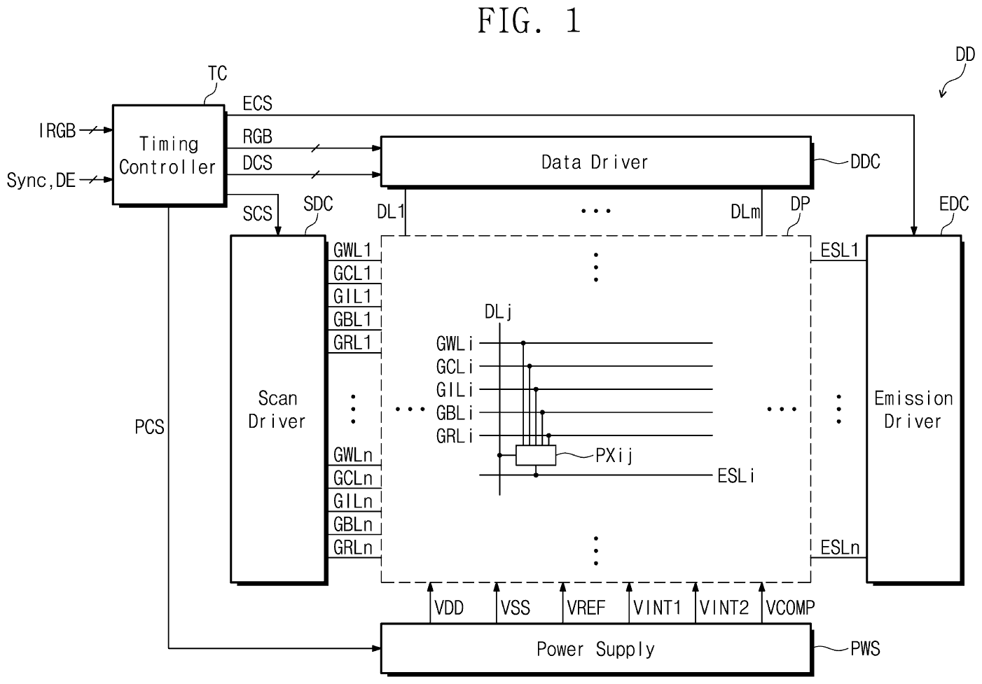

FIG. 1 is a block diagram of an electronic device DD according to an embodiment of the present disclosure.

Referring to FIG. 1, the electronic device DD may include a display panel DP, a panel driver SDC, EDC, and DDC, a power supply PWS, and a timing controller TC. In this embodiment, the display panel DP is described as an emissive display panel. The emissive display panel may include an organic light emitting display panel, an inorganic light emitting display panel, or a quantum-dot light emitting display panel. In an embodiment to be described herein, an organic light emitting display panel will be described in detail as an example. The panel driver SDC, EDC, and DDC may include a scan driver SDC, an emission driver EDC, and a data driver DDC.

The display panel DP may include scan lines GWL1 to GWLn, GCL1 to GCLn, GIL1 to GILn, GBL1 to GBLn, and GRL1 to GRLn, emission lines ESL1 to ESLn, and data lines DL1 to DLm. The display panel DP may include a plurality of pixels connected to the scan lines GWL1 to GWLn, GCL1 to GCLn, GIL1 to GILn, GBL1 to GBLn, and GRL1 to GRLn, the emission lines ESL1 to ESLn, and the data lines DL1 to DLm (here, m and n being integers greater than 1).

For example, a pixel PXij (here, i and j being integers greater than 1) located on the i-th horizontal line (or, the i-th pixel row) and the j-th vertical line (or, the j-th pixel column) may be connected to the i-th first scan line (or, write scan line) GWLi, the i-th second scan line (or, compensation scan line) GCLi, the i-th third scan line (or, first initialization scan line) GILi, the i-th fourth scan line (or, second initialization scan line) GBLi, the i-th fifth scan line (or, reset scan line) GRLi, the j-th data line DLj, and the i-th emission line ESLi.

The pixel PXij may include a plurality of light emitting elements, a plurality of transistors, and a plurality of capacitors. The pixel PXij may receive a first power supply voltage VDD, a second power supply voltage VSS, a third power supply voltage (or, a reference voltage) VREF, a fourth power supply voltage (or, a first initialization voltage) VINT1, a fifth power supply voltage (or, a second initialization voltage) VINT2, and a sixth power supply voltage (or, a compensation voltage) VCOMP through the power supply PWS.

The first power supply voltage VDD and the second power supply voltage VSS are set such that current flows through a light emitting element to cause the light emitting element to emit light. For example, the first power supply voltage VDD may be set to a voltage higher than the second power supply voltage VSS.

The third power supply voltage VREF may be a voltage for initializing a gate of a drive transistor included in the pixel PXij. The third power supply voltage VREF may be used to implement a predetermined grayscale using a voltage difference from a data signal. To achieve this, the third power supply voltage VREF may be set to a predetermined voltage within the voltage range of the data signal.

The fourth power supply voltage VINT1 may be a voltage for initializing a capacitor included in the pixel PXij. The fourth power supply voltage VINT1 may be set to a voltage lower than the third power supply voltage VREF. For example, the fourth power supply voltage VINT1 may be set to a voltage lower than the difference between the third power supply voltage VREF and the threshold voltage of the drive transistor. However, embodiments of the present disclosure are not limited thereto.

The fifth power supply voltage VINT2 may be a voltage for initializing a cathode of the light emitting element included in the pixel PXij. The fifth power supply voltage VINT2 may be set to a voltage lower than the first power supply voltage VDD or the fourth power supply voltage VINT1 or may be set to a voltage similar to, or the same as, the third power supply voltage VREF. However, without being limited thereto, the fifth power supply voltage VINT2 may be set to a voltage similar to, or the same as, the first power supply voltage VDD.

The sixth power supply voltage VCOMP may supply a predetermined current to the drive transistor when the threshold voltage of the drive transistor is compensated for.

In FIG. 1, it is illustrated that all of the first to sixth power supply voltages VDD, VSS, VREF, VINT1, VINT2, and VCOMP are supplied by the power supply PWS. However, embodiments of the present disclosure are not limited thereto. For example, both the first power supply voltage VDD and the second power supply voltage VSS may be supplied irrespective of the structure of the pixel PXij, and at least one voltage among the third power supply voltage VREF, the fourth power supply voltage VINT1, the fifth power supply voltage VINT2, and the sixth power supply voltage VCOMP may not be supplied in correspondence to the structure of the pixel PXij.

In an embodiment of the present disclosure, signal lines connected to the pixel PXij may be set in various ways in correspondence to the circuit structure of the pixel PXij.

The scan driver SDC may receive a first control signal SCS from the timing controller TC and may supply scan signals to the first scan lines GWL1 to GWLn, the second scan lines GCL1 to GCLn, the third scan lines GIL1 to GILn, the fourth scan lines GBL1 to GBLn, and the fifth scan lines GRL1 to GRLn, based on the first control signal SCS.

The scan signals may be set to voltages by which transistors receiving the scan signals are turned on. For example, a scan signal supplied to a P-type transistor may be set to a logic low level, and a scan signal supplied to an N-type transistor may be set to a logic high level. Hereinafter, when a scan signal is supplied, it may be understood that the scan signal is supplied at a logic level that turns on a transistor controlled by the scan signal.

In FIG. 1, for convenience of description, the scan driver SDC is illustrated as a single component. However, embodiments of the present disclosure are not limited thereto. In some embodiments, a plurality of scan drivers may be included to supply the scan signals to the first scan lines GWL1 to GWLn, the second scan lines GCL1 to GCLn, the third scan lines GIL1 to GILn, the fourth scan lines GBL1 to GBLn, and the fifth scan lines GRL1 to GRLn, respectively.

The emission driver EDC may supply emission signals to the emission lines ESL1 to ESLn, based on a second control signal ECS. For example, the emission signals may be sequentially supplied to the emission lines ESL1 to ESLn.

Transistors connected to the emission lines ESL1 to ESLn of the present disclosure may be implemented with N-type transistors. In this case, the emission signals supplied to the emission lines ESL1 to ESLn may be set to a gate-off voltage. The transistors receiving the emission signals may turn off when the emission signals supplied are of a gate-off voltage, and the transistors may turn on in other cases.

The second control signal ECS may include an emission start signal and clock signals, and the emission driver EDC may be implemented with a shift register that sequentially generates and outputs emission signals in a pulse form by sequentially shifting the pulsed emission start signal using the clock signals.

The data driver DDC may receive a third control signal DCS and image data RGB from the timing controller TC. The data driver DDC may convert the image data RGB in a digital format into analog data signals (e.g., data signals). The data driver DDC may supply the data signals to the data lines DL1 to DLm in correspondence to the third control signal DCS.

The third control signal DCS may include a data enable signal, a horizontal start signal, and a data clock signal that instruct output of an effective data signal. For example, the data driver DDC may include a shift register that generates a sampling signal by shifting the horizontal start signal in synchronization with the data clock signal, a latch that latches the image data RGB in response to the sampling signal, a digital-analog converter (or, a decoder) that converts the latched image data (e.g., data in a digital format) into analog data signals, and buffers (or, amplifiers) that output the data signals to the data lines DL1 to DLm.

The power supply PWS may supply, to the display panel DP, the first power supply voltage VDD, the second power supply voltage VSS, and the third power supply voltage VREF for driving the pixel PXij. The power supply PWS may supply, to the display panel DP, at least one voltage among the fourth power supply voltage VINT1, the fifth power supply voltage VINT2, and the sixth power supply voltage VCOMP.

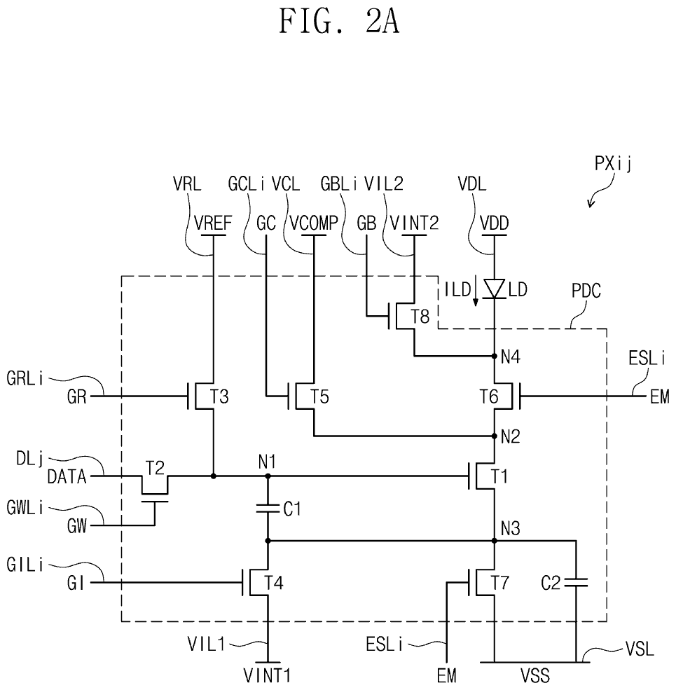

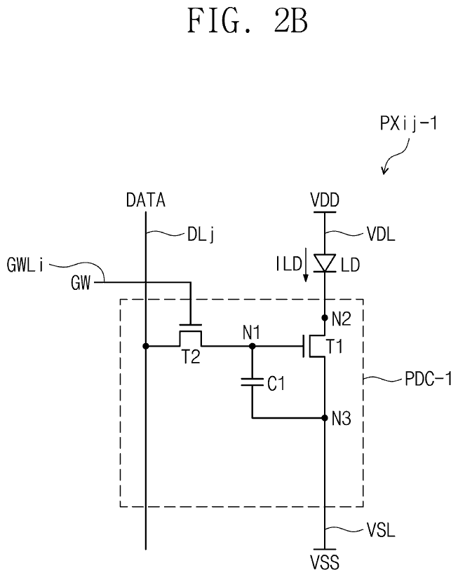

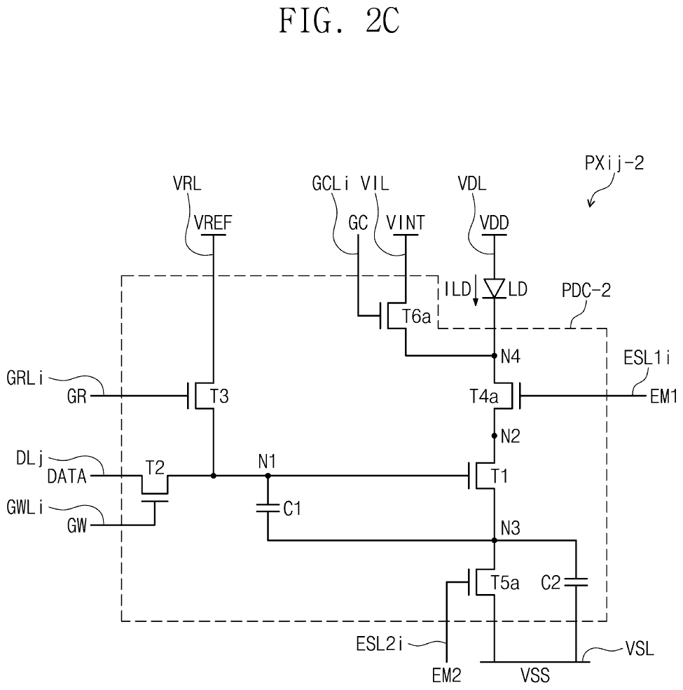

For example, the power supply PWS may supply the first power supply voltage VDD, the second power supply voltage VSS, the third power supply voltage VREF, the fourth power supply voltage VINT1, the fifth power supply voltage VINT2, and the sixth power supply voltage VCOMP to the display panel DP through a first power line VDL (refer to FIG. 2A), a second power line VSL (refer to FIG. 2A), a third power line (or, a reference voltage line) VRL (refer to FIG. 2A), a fourth power line (or, a first initialization voltage line) VIL1 (refer to FIG. 2A), a fifth power line (or, a second initialization voltage line) VIL2 (refer to FIG. 2A), and a sixth power line (or, a compensation voltage line) VCL (refer to FIG. 2A) that are not illustrated.

The power supply PWS may be implemented with a power management integrated circuit, but is not limited thereto.

The timing controller TC may generate the first control signal SCS, the second control signal ECS, the third control signal DCS, and the fourth control signal PCS, based on input image data IRGB, a synchronization signal Sync (e.g., a vertical synchronization signal, a horizontal synchronization signal, and the like), a data enable signal DE, and a clock signal. The first control signal SCS may be supplied to the scan driver SDC, the second control signal ECS may be supplied to the emission driver EDC, the third control signal DCS may be supplied to the data driver DDC, and the fourth control signal PCS may be supplied to the power supply PWS. The timing controller TC may generate the image data RGB (or, frame data) by rearranging the input image data IRGB in correspondence to the arrangement of the pixel PXij in the display panel DP.

The scan driver SDC, the emission driver EDC, the data driver DDC, the power supply PWS, and/or the timing controller TC may be directly formed on the display panel DP or may be implemented with separate driver chips and connected to the display panel DP. In some aspects, at least two of the scan driver SDC, the emission driver EDC, the data driver DDC, the power supply PWS, and the timing controller TC may be implemented with one driver chip. For example, the data driver DDC and the timing controller TC may be implemented with one driver chip.

Although the electronic device DD according to the embodiment has been described herein with reference to FIG. 1, the electronic device of embodiments of the present disclosure are not limited thereto. Signal lines may be add or omitted depending on the configuration of the pixels. In some aspects, a connection relationship between one pixel and signal lines may also be changed. In an example in which one of the signal lines is omitted, another signal line may replace the omitted signal line.

FIGS. 2A, 2B, and 2C are equivalent circuit diagrams of pixels according to embodiments of the present disclosure. In FIGS. 2A, 2B, and 2C, equivalent circuit diagrams of pixels PXij, PXij-1, and PXij-2 connected to the i-th first scan line GWLi (hereinafter, referred to as the first scan line) and the j-th data line DLj (hereinafter, referred to as the data line) are illustrated.

As illustrated in FIG. 2A, the pixel PXij includes a light emitting element LD and a pixel driver PDC. The light emitting element LD is connected to the first power line VDL and the pixel driver PDC.

The pixel driver PDC may be connected to the plurality of scan lines GWLi, GCLi, GILi, GBLi, and GRLi, the data line DLj, the emission line ESLi, and the plurality of power lines VDL, VSL, VIL1, VIL2, VRL, and VCL. The pixel driver PDC may include first to eighth transistors T1, T2, T3, T4, T5, T6, T7, and T8, a first capacitor C1, and a second capacitor C2. Hereinafter, in the examples herein, the first to eighth transistors T1, T2, T3, T4, T5, T6, T7, and T8 are all N-type transistors. However, embodiments of the present disclosure are not limited thereto. Some of the first to eighth transistors T1, T2, T3, T4, T5, T6, T7, and T8 may be N-type transistors, and the other transistors may be P-type transistors. Alternatively, each of the first to eighth transistors T1, T2, T3, T4, T5, T6, T7, and T8 may be a P-type transistor. The present disclosure is not limited to any one embodiment.

A gate of the first transistor T1 may be connected to a first node N1. A first electrode of the first transistor T1 may be connected to a second node N2, and a second electrode of the first transistor T1 may be connected to a third node N3. The first transistor T1 may be a drive transistor. The first transistor T1 may control a drive current ILD flowing from the first power line VDL to the second supply line VSL via the light emitting element LD in correspondence to the voltage of the first node N1. In this case, the first power supply voltage VDD may be set to a voltage having a higher potential than the second power supply voltage VSS.

The expression “electrically connected between a transistor and a signal line or between a transistor and a transistor” used herein means that a source, a drain, and a gate of the transistor have a one-body shape with the signal line or are connected with the signal line through a connecting electrode.

The second transistor T2 may include a gate connected to the write scan line GWLi, a first electrode connected to the data line DLj, and a second electrode connected to the first node N1. The second transistor T2 may supply a data signal DATA to the first node N1 in response to a write scan signal GW transferred through the write scan line GWLi. The second transistor T2 may turn on and electrically connect the data line DLj and the first node N1 when the write scan signal GW is supplied to the write scan line GWLi.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. In this embodiment, a gate of the third transistor T3 may receive a reset scan signal GR through the i-th fifth scan line GRLi (hereinafter, referred to as the reset scan line). The third transistor T3 may turn on and provide the reference voltage VREF to the first node N1 when the reset scan signal GR is supplied to the reset scan line GRLi.

The fourth transistor T4 may be connected between the third node N3 and the first initialization voltage line VIL1. A first electrode of the fourth transistor T4 may be connected to the third node N3, and a second electrode of the fourth transistor T4 may be connected to the first initialization voltage line VIL1 that provides the first initialization voltage VINT1. The fourth transistor T4 may be referred to as a first initialization transistor. A gate of the fourth transistor T4 may receive a first initialization scan signal GI through the i-th third scan line GILi (hereinafter, referred to as the first initialization scan line). The fourth transistor T4 may turn on and supply the first initialization voltage VINT1 to the third node N3 when the first initialization scan signal GI is supplied to the first initialization scan line GILi.

The fifth transistor T5 may be connected between the compensation voltage line VCL and the second node N2. A first electrode of the fifth transistor T5 may receive the compensation voltage VCOMP through the compensation voltage line VCL, and a second electrode of the fifth transistor T5 may be connected to the second node N2 and may be electrically connected with the first electrode of the first transistor T1. A gate of the fifth transistor T5 may receive a compensation scan signal GC through the i-th second scan line GCLi (hereinafter, referred to as the compensation scan line). The fifth transistor T5 may turn on and provide the compensation voltage VCOMP to the second node N2 when the compensation scan signal GC is supplied to the compensation scan line GCLi (e.g., during a compensation period), and the compensation voltage VCOMP may compensate for the threshold voltage of the first transistor T1 during the compensation period.

The sixth transistor T6 may be connected between the first transistor T1 and the light emitting element LD. Specifically, a gate of the sixth transistor T6 may receive an emission signal EM through the i-th emission line ESLi (hereinafter, referred to as the emission line). A first electrode of the sixth transistor T6 may be connected to a cathode of the light emitting element LD through a fourth node N4, and a second electrode of the sixth transistor T6 may be connected with the first electrode of the first transistor T1 through the second node T2. The sixth transistor T6 may be referred to as a first emission control transistor. The sixth transistor T6 may turn on and electrically connect the light emitting element LD and the first transistor T1 when the emission signal EM is supplied to the emission line ESLi.

The seventh transistor T7 may be connected between the second power line VSL and the third node N3. A first electrode of the seventh transistor T7 may be connected with the second electrode of the first transistor T1 through the third node N3, and a second electrode of the seventh transistor T7 may receive the second power supply voltage VSS through the second power line VSL. A gate of the seventh transistor T7 may be electrically connected to the emission line ESLi. The seventh transistor T7 may be referred to as a second emission control transistor. The seventh transistor T7 may turn on and electrically connect the second electrode of the first transistor T1 and the second power line VSL when the emission signal EM is supplied to the emission line ESLi.

In this embodiment, the sixth transistor T6 and the seventh transistor T7 are illustrated as being connected to the same emission line ESLi and turned on through the same emission signal EM. However, this is illustrative, and the sixth transistor T6 and the seventh transistor T7 may be independently turned on by different signals distinguished from each other. Furthermore, in the pixel driver PDC according to an embodiment of the present disclosure, one of the sixth transistor T6 and the seventh transistor T7 may be omitted.

The eighth transistor T8 may be connected between the second initialization voltage line VIL2 and the fourth node N4. That is, the eighth transistor T8 may include a gate connected to the i-th fourth scan line GBLi (hereinafter, referred to as the second initialization scan line), a first electrode connected to the second initialization voltage line VIL2, and a second electrode connected to the fourth node N4. The eighth transistor T8 may be referred to as a second initialization transistor. The eighth transistor T8 may supply the second initialization voltage VINT2 to the fourth node N4 corresponding to the cathode of the light emitting element LD in response to a second initialization scan signal GB transferred through the second initialization scan line GBLi. The cathode of the light emitting element LD may be initialized by the second initialization voltage VINT2.

In this embodiment, some of the second to eighth transistors T2, T3, T4, T5, T6, T7, and T8 may be simultaneously turned on through the same scan signal. For example, the eighth transistor T8 and the fifth transistor T5 may be simultaneously turned on through the same scan signal. For example, the eighth transistor T8 and the fifth transistor T5 may be operated by the same compensation scan signal GC. The eighth transistor T8 and the fifth transistor T5 may be simultaneously turned on/off by the same compensation scan signal GC. In this case, the compensation scan line GCLi and the second initialization scan line GBLi may be substantially provided as a single scan line. Accordingly, initialization of the cathode of the light emitting element LD and compensation of the threshold voltage of the first transistor T1 may be performed at the same timing. However, this is illustrative, and the present disclosure is not limited to any one embodiment.

In some aspects, according to the present disclosure, the initialization of the cathode of the light emitting element LD and the compensation of the threshold voltage of the first transistor T1 may be performed by the application of the same power supply voltage. For example, the compensation voltage line VCL and the second initialization voltage line VIL2 may be substantially provided as a single power supply voltage line. In this case, the cathode initialization operation and the drive transistor compensation operation may be performed with a single power supply voltage, and thus the driver design may be simplified. However, this is illustrative, and the present disclosure is not limited to any one embodiment.

The first capacitor C1 may be disposed between the first node N1 and the third node N3. The first capacitor C1 may store a difference voltage between the first node N1 and the third node N3. The first capacitor C1 may be referred to as a storage capacitor.

The second capacitor C2 may be disposed between the third node N3 and the second power line VSL. That is, one electrode of the second capacitor C2 may be connected to the second power line VSL that receives the second power supply voltage VSS, and an opposite electrode of the second capacitor C2 may be connected to the third node N3. The second capacitor C2 may store charges corresponding to a voltage difference between the second power supply voltage VSS and the third node N3. The second capacitor C2 may be referred to as a hold capacitor. The second capacitor C2 may have a higher storage capacity than the first capacitor C1. Accordingly, the second capacitor C2 may minimize a voltage change at the third node N3 in correspondence to a voltage change at the first node N1.

In this embodiment, the light emitting element LD may be connected with the pixel driver PDC through the fourth node N4. The light emitting element LD may include an anode connected to the first power line VDL and the cathode opposite the anode. In this embodiment, the light emitting element LD may be connected with the pixel driver PDC through the cathode. That is, in the pixel PXij according to the present disclosure, a connection node at which the light emitting element LD and the pixel driver PDC are connected may be the fourth node N4, and the fourth node N4 may correspond to a connection node between the first electrode of the sixth transistor T6 and the cathode of the light emitting element LD. Accordingly, the potential of the fourth node N4 may substantially correspond to the potential of the cathode of the light emitting element LD.

Specifically, the anode of the light emitting element LD may be connected to the first power line VDL and may receive the first power supply voltage VDD that is a constant voltage, and the cathode may be connected to the first transistor T1 through the sixth transistor T6. That is, in this embodiment in which the first to eighth transistors T1 to T8 are N-type transistors, the potential of the third node N3 corresponding to the source of the first transistor T1, which is a drive transistor, may not be directly affected by characteristics of the light emitting element LD. Accordingly, even though degradation of the light emitting element LD occurs, an influence on the transistors constituting the pixel driver PDC, particularly, the gate-source voltage Vgs of the drive transistor may be reduced. That is, the amount of change in the drive current due to the degradation of the light emitting element LD may be reduced. Thus, an afterimage defect of the display panel depending on an increase in usage time may be decreased, and the lifespan may be improved.

Alternatively, as illustrated in FIG. 2B, the pixel PXij-1 may include a pixel driver PDC-1 that includes two transistors T1 and T2 and one capacitor C1. The pixel driver PDC-1 may be connected to a light emitting element LD, the write scan line GWLi, the data line DLj, and the second power line VSL. The pixel driver PDC-1 illustrated in FIG. 2B may correspond to a structure in which the third to eighth transistors T3 to T8 and the second capacitor C2 are omitted from the pixel driver PDC illustrated in FIG. 2A.

Each of the first transistor T1 and the second transistor T2 may be an N-type transistor or a P-type transistor. In this example embodiment, each of the first transistor T1 and the second transistor T2 is an N-type transistor.

The first transistor T1 may include a gate connected to a first node N1, a first electrode connected to a second node N2, and a second electrode connected to a third node N3. The second node N2 may be a node connected to the first power line VDL side, and the third node N3 may be a node connected to the second power line VSL side. The first transistor T1 may be connected to the light emitting element LD through the second node N2 and may be connected to the second power line VSL through the third node N3. The first transistor T1 may be a drive transistor.

The second transistor T2 may include a gate that receives the write scan signal GW through the write scan line GWLi, a first electrode connected to the data line DLj, and a second electrode connected to the first node N1. The second transistor T2 may supply the data signal DATA to the first node N1 in response to the write scan signal GW transferred through the write scan line GWLi.

The first capacitor C1 may include an electrode connected to the first node N1 and an electrode connected to the third node N3. The first capacitor C1 may store the data signal DATA transferred to the first node N1.

The light emitting element LD may include an anode and a cathode. In this embodiment, the anode of the light emitting element LD is connected with the first power line VDL, and the cathode of the light emitting element LD is connected with the pixel driver PDC-1 through the second node N2. In this embodiment, the cathode of the light emitting element LD may be connected with the first transistor T1. The light emitting element LD may emit light in correspondence to the amount of current flowing through the first transistor T1 of the pixel driver PDC-1.

In this embodiment in which the first transistor T1 and the second transistor T2 are N-type transistors, the second node N2 at which the cathode of the light emitting element LD and the pixel driver PDC-1 are connected may correspond to the drain of the first transistor TI. That is, a change in the gate-source voltage Vgs of the first transistor T1 due to the light emitting element LD may be prevented. Accordingly, the amount of change in drive current due to degradation of the light emitting element LD may be reduced. Thus, an afterimage defect of the display panel depending on an increase in usage time may be decreased, and the lifespan may be improved.

In another case, as illustrated in FIG. 2C, the pixel PXij-2 may include a pixel driver PDC-2 that includes six transistors T1, T2, T3, T4a, T5a, and T6a and two capacitors C1 and C2.

The pixel driver PDC-2 may be connected to a light emitting element LD, the write scan line GWLi, the reset scan line GRLi, the compensation scan line GCLi, the i-th first emission line ESL1i (hereinafter, referred to as the first emission line), the i-th second emission line ESL2i (hereinafter, referred to as the second emission line), the data line DLj, the first power line VDL, the second power line VSL, the third power line VRL, and an initialization voltage line VIL.

The pixel driver PDC-2 illustrated in FIG. 2C may be similar to a structure in which the fourth transistor T4 and the fifth transistor T5 are omitted from the pixel driver PDC illustrated in FIG. 2A. The area of the pixel driver PDC-2 illustrated in FIG. 2C may be smaller than the area of the pixel driver PDC-1 illustrated in FIG. 2A, and thus high resolution may be more easily implemented.

Each of the first to sixth transistors T1, T2, T3, T4a, T5a, and T6a may be an N-type transistor or a P-type transistor. In this example embodiment, each of the first to sixth transistors T1, T2, T3, T4a, T5a, and T6a is an N-type transistor.

The first transistor T1 may include a gate connected to a first node N1, a first electrode connected to a second node N2, and a second electrode connected to a third node N3. The second node N2 may be a node connected to the first power line VDL side, and the third node N3 may be a node connected to the second power line VSL side. The first transistor T1 may be connected to the light emitting element LD through the second node N2 and may be connected to the second power line VSL through the third node N3. The first transistor T1 may be a drive transistor.

The second transistor T2 may include a gate that receives the write scan signal GW through the write scan line GWLi, a first electrode connected to the data line DLj, and a second electrode connected to the first node N1. The second transistor T2 may supply the data signal DATA to the first node N1 in response to the write scan signal GW transferred through the write scan line GWLi.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. In this embodiment, a gate of the third transistor T3 may receive the reset scan signal GR through the reset scan line GRLi. The third transistor T3 may turn on and provide the reference voltage VREF to the first node N1 when the reset scan signal GR is supplied to the reset scan line GRLi.

The fourth transistor T4a may be connected between the first transistor T1 and the light emitting element LD. Specifically, a gate of the fourth transistor T4a may receive a first emission signal EM1 through the first emission line ESL1i. A first electrode of the fourth transistor T4a may be connected to a cathode of the light emitting element LD through a fourth node N4, and a second electrode of the fourth transistor T4a may be connected with the first electrode of the first transistor T1 through the second node T2. The fourth transistor T4a may be referred to as a first emission control transistor. The fourth transistor T4a may turn on and electrically connect the light emitting element LD and the first transistor T1 when the first emission signal EM 1 is supplied to the first emission line ESL1i.

The fifth transistor T5a may be connected between the second power line VSL and the third node N3. A first electrode of the fifth transistor T5a may be connected with the second electrode of the first transistor T1 through the third node N3, and a second electrode of the fifth transistor T5a may receive the second power supply voltage VSS through the second power line VSL. A gate of the fifth transistor T5a may be electrically connected to the second emission line ESL2i. The fifth transistor T5a may be referred to as a second emission control transistor. The fifth transistor T5a may turn on and electrically connect the second electrode of the first transistor T1 and the second power line VSL when a second emission signal EM2 is supplied to the second emission line ESL2i.

In this embodiment, the fourth transistor T4a and the fifth transistor T5a may be connected to the first emission line ESL1i and the second emission line ESL2i distinguished from each other and may be turned on through the first emission signal EM1 and the second emission signal EM2 distinguished from each other. That is, the fourth transistor T4a and the fifth transistor T5a may be turned on independently of each other. However, this is an example, and embodiments of the present disclosure are not limited thereto. For example, in an embodiment of the present disclosure, the fourth transistor T4a and the fifth transistor T5a may be connected to the same emission line and may be controlled by the same emission signal. Furthermore, in the pixel driver PDC-2 according to an embodiment of the present disclosure, one of the fourth transistor T4a and the fifth transistor T5a may be omitted.

The sixth transistor T6a may be connected between the initialization voltage line VIL and the fourth node N4. That is, the sixth transistor T6a may include a gate connected to the compensation scan line GCLi, a first electrode connected to the initialization voltage line VIL, and a second electrode connected to the fourth node N4. The sixth transistor T6a may be referred to as an initialization transistor. The sixth transistor T6a may supply an initialization voltage VINT to the fourth node N4 corresponding to the cathode of the light emitting element LD in response to the compensation scan signal GC transferred through the compensation scan line GCLi. The cathode of the light emitting element LD may be initialized by the initialization voltage VINT.

The first capacitor C1 may be disposed between the first node N1 and the third node N3. The first capacitor C1 may store a difference voltage between the first node N1 and the third node N3. The first capacitor C1 may be referred to as a storage capacitor.

The second capacitor C2 may be disposed between the third node N3 and the second power line VSL. That is, one electrode of the second capacitor C2 may be connected to the second power line VSL that receives the second power supply voltage VSS, and an opposite electrode of the second capacitor C2 may be connected to the third node N3. The second capacitor C2 may store charges corresponding to a voltage difference between the second power supply voltage VSS and the third node N3. The second capacitor C2 may be referred to as a hold capacitor.

The light emitting element LD may include an anode and the cathode. In this embodiment, the anode of the light emitting element LD is connected with the first power line VDL, and the cathode of the light emitting element LD is connected with the pixel driver PDC-2 through the fourth node N4. In this embodiment, the cathode of the light emitting element LD may be connected with the first transistor T1 through the fourth transistor T4a. The light emitting element LD may emit light in correspondence to the amount of current flowing through the first transistor T1 of the pixel driver PDC-2.

In this embodiment in which the first to sixth transistors T1, T2, T3, T4a, T5a, and T6a are N-type transistors, the potential of the third node N3 corresponding to the source of the first transistor T1, which is a drive transistor, may not be directly affected by characteristics of the light emitting element LD. Accordingly, even though degradation of the light emitting element LD occurs, an influence on the transistors constituting the pixel driver PDC-2, particularly, the gate-source voltage Vgs of the drive transistor may be reduced. That is, the amount of change in drive current due to the degradation of the light emitting element LD may be reduced. Thus, an afterimage defect of the display panel depending on an increase in usage time may be decreased, and the lifespan may be improved.

In FIGS. 2A, 2B, and 2C, the circuits for the pixel drivers PDC, PDC-1, and PDC-2 according to the embodiments of the present disclosure are illustrated. In the display panel according to an embodiment of the present disclosure, the number or arrangement relationship of transistors and the number or arrangement relationship of capacitors may be designed in various ways as long as a circuit is connected with a cathode of a light emitting element LD, and the present disclosure is not limited to any one embodiment.

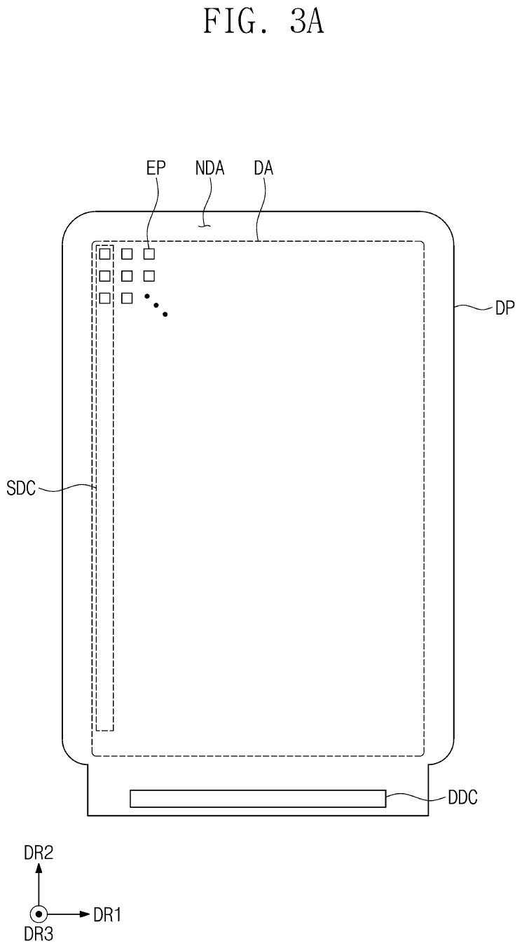

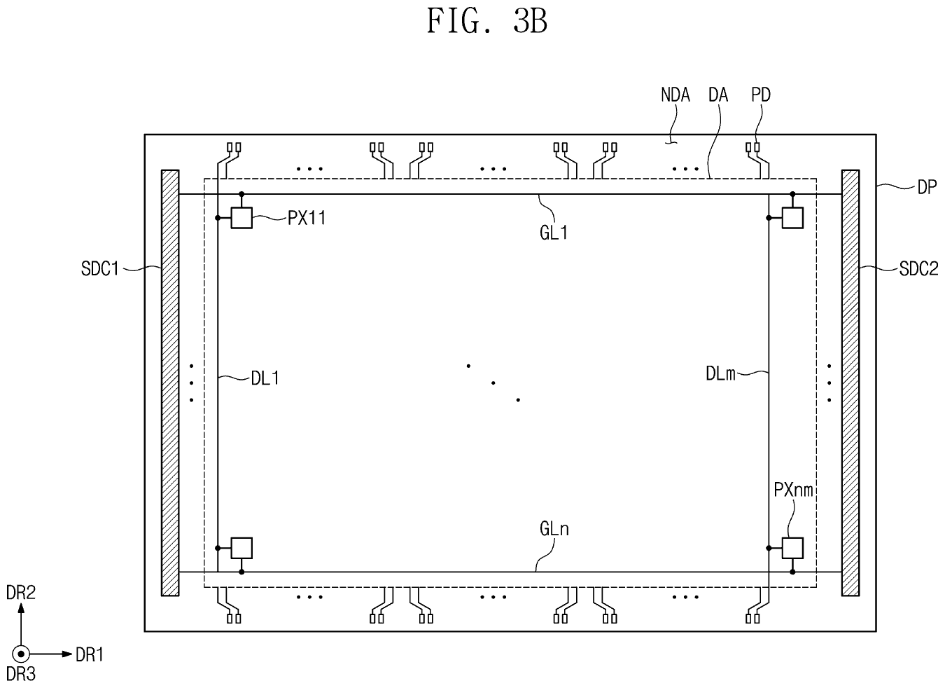

FIGS. 3A and 3B are schematic plan views illustrating the display panel according to an embodiment of the present disclosure. In each of FIGS. 3A and 3B, some components are omitted. Hereinafter, the present disclosure will be described with reference to FIGS. 3A and 3B.

Referring to FIG. 3A, the display panel DP of an embodiment may be divided into a display area DA and a peripheral area (or, a non-display area) NDA. The display area DA may include a plurality of light emitting parts EP.

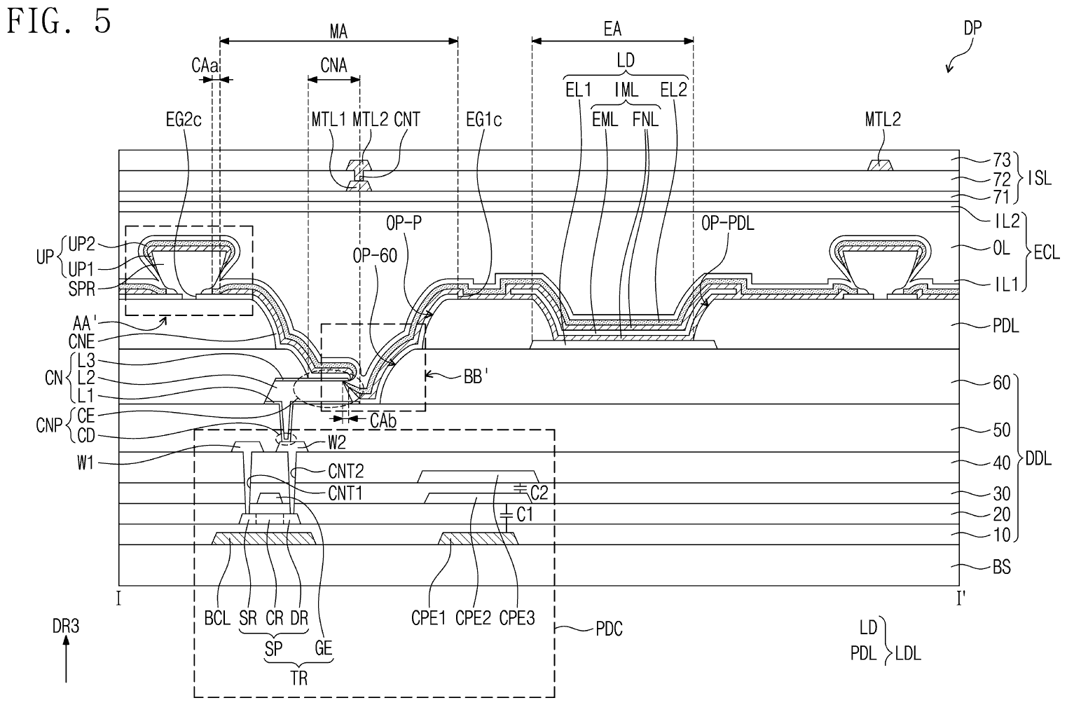

The light emitting parts EP may be areas where light is emitted by the pixels PXij (refer to FIG. 1). Specifically, each of the light emitting parts EP may correspond to a light emitting opening OP-PDL (refer to FIG. 5) that will be described herein. The light emitting opening OP-PDL may be referred to as an aperture or an opening.

The peripheral area NDA may be disposed adjacent to the display area DA. In this embodiment, the peripheral area NDA is illustrated in a shape surrounding the periphery of the display area DA. However, this is illustrative, and the peripheral area NDA may be disposed on one side of the display area DA or may be omitted and is not limited to any one embodiment.

In this embodiment, the scan driver SDC and the data driver DDC may be mounted on the display panel DP. In an embodiment, the scan driver SDC may be disposed in the display area DA, and the data driver DDC may be disposed in the peripheral area NDA. The scan driver SDC, when viewed from above the plane, may overlap at least some of the plurality of light emitting parts EP disposed in the display area DA. Since the scan driver SDC is disposed in the display area DA, the area of the peripheral area NDA may be smaller than the area of a peripheral area of a display panel in the related art in which a scan driver is disposed in the peripheral area, and the electronic device having a thin bezel may be easily implemented.

In some embodiments, unlike that illustrated in FIG. 3A, the scan driver SDC may be implemented with two parts separated from each other. The two scan drivers SDC may be spaced apart from each other in the left-right direction with the center of the display area DA between the two scan drivers SDC. Alternatively, the scan driver SDC may be implemented with two or more scan drivers. However, the present disclosure is not limited to any one embodiment.

FIG. 3A illustrates an example of the display panel, and the data driver DDC may be disposed in the display area DA. In this case, some of the light emitting parts EP disposed in the display area DA may overlap the data driver DDC when viewed from above the plane.

In an embodiment, the data driver DDC may be provided in the form of a separate driver chip independent of the display panel DP and may be connected to the display panel DP. However, this is illustrative, and the data driver DDC may be formed in the same process as the scan driver SDC to constitute the display panel DP and is not limited to any one embodiment.

As illustrated in FIG. 3B, the display panel DP may have a shape in which the length corresponding to a first direction DR1 is greater than the length corresponding to a second direction DR2. A plurality of pixels PX11 to PXnm arranged in n rows and m columns are disposed in the display area DA. In this embodiment, the display panel DP may include a plurality of scan drivers SDC1 and SDC2. The scan drivers SDC1 and SDC2 include the first scan driver SDC1 and the second scan driver SDC2 spaced apart from each other in the first direction DR1.

The first scan driver SDC1 may be connected with some of the scan lines GL1 to GLn, and the second scan driver SDC2 may be connected with the other scan lines. For example, the first scan driver SDC1 may be connected to odd-numbered scan lines among the scan lines GL1 to GLn, and the second scan driver SDC2 may be connected to even-numbered scan lines among the scan lines GL1 to GLn.

In FIG. 3B, for ease of description, pads PD of the data lines DL1 to DLm are illustrated. The pads PD may be defined at ends of the data lines DL1 to DLm. The data lines DL1 to DLm may be connected to the data driver DDC (refer to FIG. 3A) through the pads PD.

According to the present disclosure, the pads PD may be arranged in opposite regions of the peripheral area NDA spaced apart from each other with the display area DA between the opposite regions. For example, some of the pads PD may be disposed on the upper side, that is, on one side adjacent to the first scan line GL1 among the scan lines GL1 to GLn, and the other pads may be disposed on the lower side, that is, on an opposite side adjacent to the last scan line GLn among the scan lines GL1 to GLn. In this embodiment, pads PD connected to odd-numbered data lines among the data lines DL1 to DLm may be disposed on the upper side, and pads PD connected to even-numbered data lines among the data lines DL1 to DLm may be disposed on the lower side.

Although not illustrated, the display panel DP may include a plurality of upper data drivers connected with the pads PD disposed on the upper side and/or a plurality of lower data drivers connected with the pads PD disposed on the lower side. However, this is illustrative, and the display panel DP may include one upper data driver connected with the pads PD disposed on the upper side and/or one lower data driver connected with the pads PD disposed on the lower side. The pads PD according to an embodiment of the present disclosure may be disposed on one side of (e.g., on only one side of) the display panel DP and connected to a single data driver and are not limited to any one embodiment.

In some aspects, as described herein with reference to FIG. 3A, the display panel DP of FIG. 3B may also include a scan driver and/or a data driver disposed in the display area DA. Accordingly, some of the light emitting parts disposed in the display area DA may overlap the scan driver and/or the data driver when viewed from above the plane.

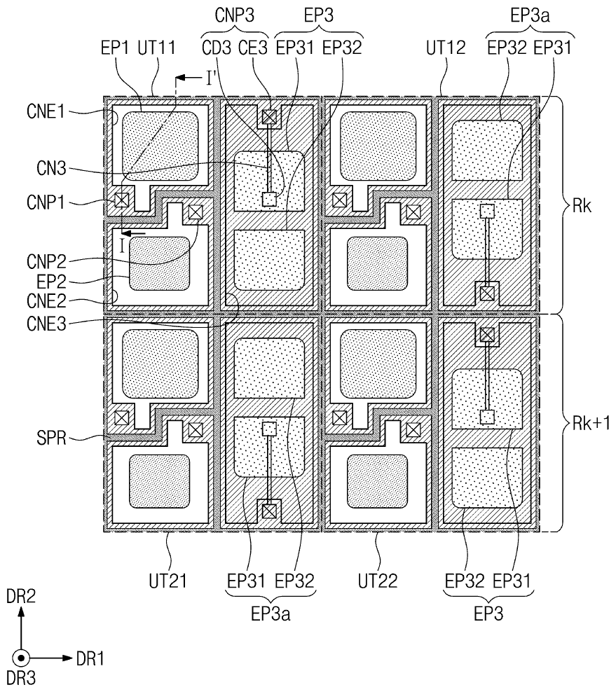

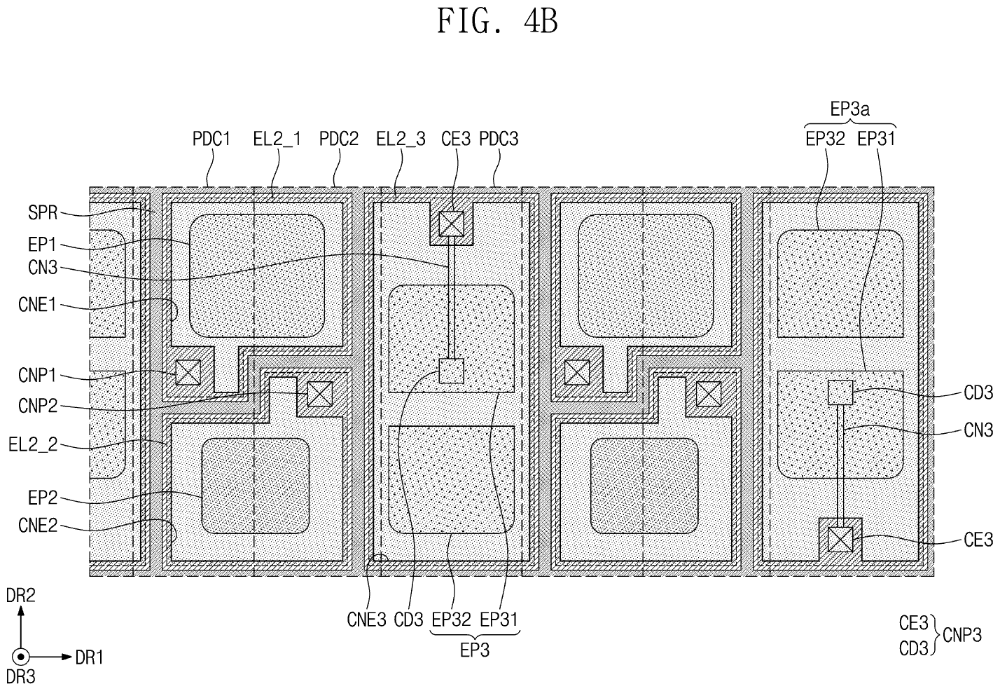

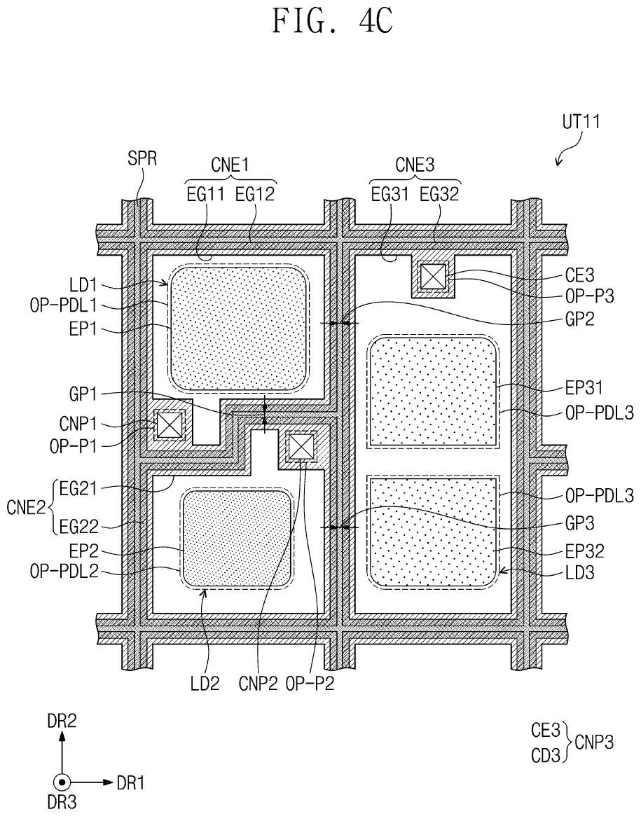

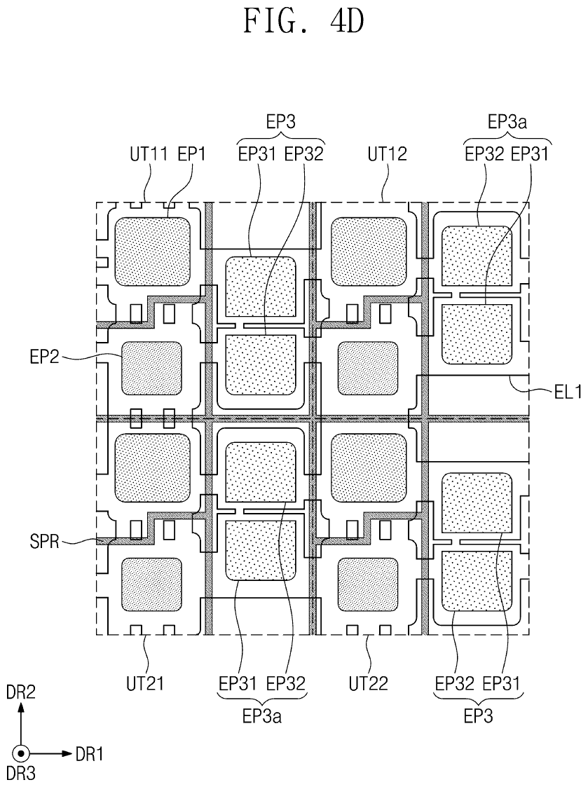

FIGS. 4A to 4D are enlarged plan views of partial areas of the display panel according to embodiments of the present disclosure.

In FIG. 4A, light emitting units UT11, UT12, UT21, and UT22 arranged in two rows and two columns are illustrated. Referring to FIG. 4A, light emitting parts in the first row Rk include light emitting parts that constitute the light emitting unit UT11 at the first row and the first column and the light emitting unit UT12 at the first row and the second column, and light emitting parts in the second row Rk+1 include light emitting parts that constitute the light emitting unit UT21 at the second row and the first column and the light emitting unit UT22 at the second row and the second column.

Each of light emitting parts EP1, EP2, and EP3 may correspond to the light emitting opening OP-PDL (refer to FIG. 5) that will be described herein. That is, each of the light emitting parts EP1, EP2, and EP3 may be an area through which light is emitted by the described light emitting element. The light emitting parts EP1, EP2, and EP3 may correspond to a unit that forms an image displayed on the display panel DP (refer to FIG. 1). More specifically, each of the light emitting parts EP1, EP2, and EP3 may correspond to an area defined by the light emitting opening OP-PDL that will be described herein, particularly, an area defined by the lower surface of the light emitting opening OP-PDL.

The light emitting parts EP1, EP2, and EP3 may include the first light emitting part EPI, the second light emitting part EP2, and the third light emitting part EP3. The first light emitting part EP1, the second light emitting part EP2, and the third light emitting part EP3 may emit light of different colors. For example, the first light emitting part EP1 may emit red light, the second light emitting part EP2 may emit green light, and the third light emitting part EP3 may emit blue light. However, a combination of colors is not limited thereto. Alternatively, at least two of the first to third light emitting parts EP1, EP2, and EP3 may emit light of the same color. For example, the first to third light emitting parts EP1, EP2, and EP3 may all emit blue light or white light.

Among the first to third light emitting parts EP1, EP2, and EP3, the third light emitting part EP3 that displays light emitted by a third light emitting element may include two sub-light emitting parts EP31 and EP32 spaced apart from each other in the second direction DR2. However, this is illustrative. Likewise to the first light emitting part EPI and the second light emitting part EP2, the third light emitting part EP3 may be provided as one pattern having a one-body shape, and at least one of the first light emitting part EP1 and the second light emitting part EP2 may include sub-light emitting parts spaced apart from each other. The present disclosure is not limited to any one embodiment.

The light emitting parts in the first row Rk may include the first to third light emitting parts EP1, EP2, and EP3 constituting the light emitting unit UT11 at the first row and the first column and the first to third light emitting parts EP1, EP2, and EP3a constituting the light emitting unit UT12 at the first row and the second column, and the light emitting parts in the second row Rk+1 may include the first to third light emitting parts EP1, EP2, and EP3a constituting the light emitting unit UT21 at the second row and the first column and the first to third light emitting parts EP1, EP2, and EP3 constituting the light emitting unit UT22 at the second row and the second column.

In an embodiment of the present disclosure, the light emitting parts constituting the light emitting unit UT11 at the first row and the first column may have substantially the same shape as the light emitting parts constituting the light emitting unit UT22 at the second row and the second column. In some aspects, the light emitting parts constituting the light emitting unit UT12 at the first row and the second column may have substantially the same shape as the light emitting parts constituting the light emitting unit UT21 at the second row and the first column. The light emitting parts constituting the light emitting unit UT11 at the first row and the first column may have a shape different from the shape of the light emitting parts constituting the light emitting unit UT12 at the first row and the second column. For example, some of the light emitting parts in the first row Rk and some of the light emitting parts in the second row Rk+1 may have symmetrical shapes.

In an embodiment of the present disclosure, the shape and arrangement of the third light emitting part EP3a of the light emitting unit UT21 at the second row and the first column and the shape and arrangement of the third light emitting part EP3 of the light emitting unit UT11 at the first row and the first column may have line symmetry with respect to an axis parallel to the first direction DR1, and the shape and arrangement of the third light emitting part EP3 of the light emitting unit UT22 at the second row and the second column and the shape and arrangement of the third light emitting part EP3a of the light emitting unit UT12 at the first row and the second column may have line symmetry with respect to an axis parallel to the first direction DR1. However, this is illustrative, and embodiments of the present disclosure are not limited thereto.

In FIG. 4B, light emitting parts arranged in one row are illustrated. In FIG. 4B, for ease of description, a plurality of second electrodes EL2_1, EL2_2, and EL2_3, a plurality of pixel drivers PDC1, PDC2, and PDC3, first to third connecting electrodes CNE1, CNE2, and CNE3, and a separator SPR are illustrated. Among the components of the display panel, the separator SPR, the plurality of light emitting parts EP1, EP2, and EP3 disposed in areas partitioned by the separator SPR, and the plurality of connecting electrodes CNE1, CNE2, and CNE3 are illustrated in FIG. 4C.

Referring to FIGS. 4B and 4C, the second electrodes EL2_1, EL2_2, and EL2_3 may be separated and electrically disconnected from one another by the separator SPR. In this embodiment, one light emitting unit UT11 may include three light emitting parts EP1, EP2, and EP3. Accordingly, the light emitting unit UT11 may include three second electrodes EL2_1, EL2_2, and EL2_3 (hereinafter, referred to as the first to third cathodes), three pixel drivers PDC1, PDC2, and PDC3, and three connecting lines CNE1, CNE2, and CNE3. However, this is illustrative, and the number and arrangement of light emitting parts included in the light emitting unit UT11 may be designed in various ways and are not limited to any one embodiment.

The first to third pixel drivers PDC1, PDC2, and PDC3 are electrically connected to first to third light emitting elements LD1, LD2, and LD3 including the first to third light emitting parts EP1, EP2, and EP3, respectively. The expression “connected” used herein includes not only physical direct contact but also electrical connection.

In some aspects, each of the areas where the first to third pixel drivers PDC1, PDC2, and PDC3 are defined on the plane as illustrated in FIG. 4B may correspond to a unit in which the transistors and the capacitor elements that constitute the circuit PDC (refer to FIG. 2A) for driving the light emitting element of the pixel are repeatedly arranged.

The first to third pixel drivers PDC1, PDC2, and PDC3 may be sequentially arranged in the first direction DR1. In some aspects, the positions of the first to third pixel drivers PDC1, PDC2, and PDC3 may be independently designed irrespective of the positions or shapes of the first to third light emitting parts EP1, EP2, and EP3.

For example, the first to third pixel drivers PDC1, PDC2, and PDC3 may be disposed at positions different from the areas partitioned and defined by the separator SPR (that is, the positions where the first to third cathodes EL2_1, EL2_2, and EL2_3 are disposed) or may be designed to have shapes and areas different from those of the first to third cathodes EL2_1, EL2_2, and EL2_3. Alternatively, the first to third pixel drivers PDC1, PDC2, and PDC3 may be disposed to overlap the positions where the first to third light emitting parts EP1, EP2, and EP3 exist and may be designed in shapes similar to the shapes of the areas partitioned and defined by the separator SPR, for example, the first to third cathodes EL2_1, EL2_2, and EL2_3.

In this embodiment, the first to third pixel drivers PDC1, PDC2, and PDC3 are illustrated in a rectangular shape, the first to third light emitting parts EP1, EP2, and EP3 have smaller areas than the first to third pixel drivers PDC1, PDC2, and PDC3 and are arranged in a form different from the form of the first to third pixel drivers PDC1, PDC2, and PDC3, and the first to third cathodes EL2_1, EL2_2, and EL2_3 are disposed at positions overlapping the first to third light emitting parts EPI, EP2 and EP3 and illustrated in an irregular shape.

Accordingly, as illustrated in FIG. 4B, the first pixel driver PDC1 may be disposed at a position that partially overlaps the first light emitting part EP1, the second light emitting part EP2, and another adjacent light emitting unit. The second pixel driver PDC2 may be disposed at a position that overlaps the first light emitting part EP1, the second light emitting part EP2, and the third cathode EL2_3. The third pixel driver PDC3 may be disposed at a position that overlaps the third light emitting part EP3. This is illustrative, and the positions of the first to third pixel drivers PDC1, PDC2, and PDC3 may be designed in various forms and arrangements independently of the first to third light emitting parts EPI, EP2, and EP3 and are not limited to any one embodiment.

The light emitting unit UT11 may include the first to third connecting electrodes CNE1, CNE2, and CNE3. The first connecting electrode CNE1 may electrically connect the first light emitting element LD1 that forms the first light emitting part EP1 (or, has the first light emitting part EP1 defined therein) and the first pixel driver PDC1, the second connecting electrode CNE2 may electrically connect the second light emitting element LD2 that forms the second light emitting part EP2 and the second pixel driver PDC2, and the third connecting electrode CNE3 may electrically connect the third light emitting element LD3 that forms the third light emitting part EP3 and the third pixel driver PDC3.

Specifically, the first to third connecting electrodes CNE1, CNE2, and CNE3 may electrically connect the first to third cathodes EL2_1, EL2_2, and EL2_3 and the first to third pixel drivers PDC1, PDC2, and PDC3 in a one-to-one correspondence.

Each of the first to third connecting electrodes CNE1, CNE2, and CNE3 may be disposed on a pixel defining layer PDL (refer to FIG. 5) that will be described herein. The first to third connecting electrodes CNE1, CNE2, and CNE3 may have ring shapes that surround the corresponding first to third light emitting parts EP1, EP2, and EP3. In an embodiment of the present disclosure, each of the first to third connecting electrodes CNE1, CNE2, and CNE3 is illustrated as having a closed-line ring shape, but is not limited thereto. For example, at least some of the first to third connecting electrodes CNE1, CNE2, and CNE3 may have an open ring shape with a portion broken.

Since the first to third connecting electrodes CNE1, CNE2, and CNE3 have a ring shape, the degree of freedom of the positions at which the first to third connecting electrodes CNE1, CNE2, and CNE3 and the first to third pixel drivers PDC1, PDC2, and PDC3 are connected may be improved. For example, the first connecting electrode CNE1 may be connected to the first pixel driver PDC1 through a first connection part CNP1, the second connecting electrode CNE2 may be connected to the second pixel driver PDC2 through a second connection part CNP2, and the third connecting electrode CNE3 may be connected to the third pixel driver PDC3 through a third connection part CNP3.

In an embodiment of the present disclosure, the third pixel driver PDC3 and the third light emitting element LD3 constituting the third light emitting part EP3 may be electrically connected through a connecting line CN3. Specifically, the connecting line CN3 may correspond to the node (refer to the fourth node N4 of FIG. 2A, the second node N2 of FIG. 2B, or the fourth node N4 of FIG. 2C) where the light emitting element LD (refer to FIG. 2) is connected to the pixel driver (PDC of FIG. 2A, PDC-1 of FIG. 2B, or PDC-2 of FIG. 2C). The connecting line CN3 may include a light emitting connection part CE3 and a drive connection part CD3. The light emitting connection part CE3 may be provided on one side of the connecting line CN3, and the drive connection part CD3 may be provided on an opposite side of the connecting line CN3.

The drive connection part CD3 may be a part of the connecting line CN3 connected with the pixel driver PDC3. In this embodiment, the drive connection part CD3 may be connected with one electrode of a transistor constituting the pixel driver PDC3. Specifically, the drive connection part CD3 may be connected to the drain of the sixth transistor T6 illustrated in FIG. 2A, the drain of the first transistor T1 illustrated in FIG. 2B, or the drain of the fourth transistor T4a illustrated in FIG. 2C. Accordingly, the position of the drive connection part CD3 may correspond to the position of the transistor of the pixel driver that is physically connected with the connecting line CN3.

The light emitting connection part CE3 may be a part of the connecting line CN3 connected with the light emitting element LD3. In this embodiment, the light emitting connection part CE3 may be connected with the connecting electrode CNE3.

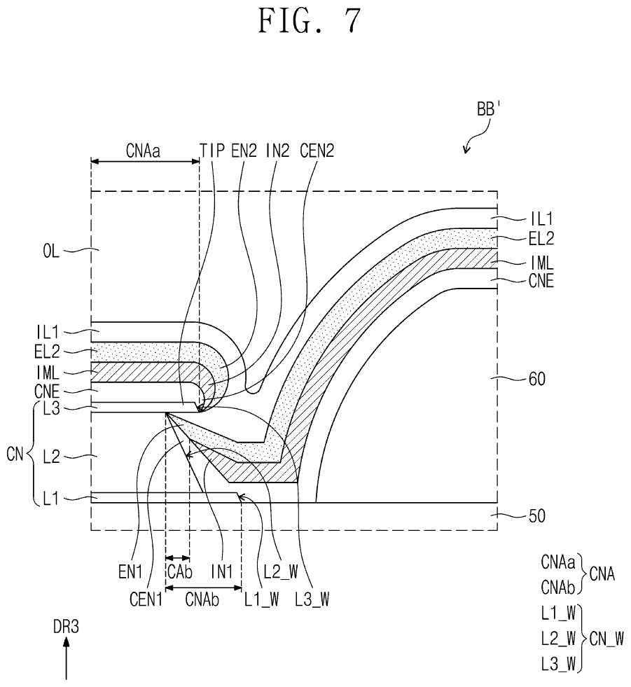

Although the connecting line CN3 connecting the third pixel driver PDC3 and the third light emitting element LD3 is illustrated in FIGS. 4A and 4B, the first pixel driver PDC1 and the first light emitting element LD1 may also be electrically connected through a connecting line CN (refer to FIG. 5), and the second pixel driver PDC2 and the second light emitting element LD2 may also be electrically connected through a connecting line CN (refer to FIG. 5). In some aspects, although the drive connection part CD3 and the light emitting connection part CE3 included in the third connection part CNP3 are illustrated in FIGS. 4A and 4B, each of the first connection part CNP1 and the second connection part CNP2 may also include a drive connection part CD (refer to FIG. 5) and a light emitting connection part CE (refer to FIG. 5). More detailed description of the connecting line CN, the drive connection part CD, and the light emitting connection part CE will be given below with reference to FIGS. 5 and 7.

The first connecting electrode CNE1 may include a first edge EG11 surrounding at least a portion of the first light emitting part EP1 and a second edge EG12 surrounding the first edge EG11. The second connecting electrode CNE2 may include a first edge EG21 surrounding at least a portion of the second light emitting part EP2 and a second edge EG22 surrounding the first edge EG21. The third connecting electrode CNE3 may include a first edge EG31 surrounding at least a portion of the third light emitting part EP3 and a second edge EG32 surrounding the first edge EG31.

The first to third connecting electrodes CNE1, CNE2, and CNE3 may be arranged spaced apart from one another. For example, the gap GP1, GP2, or GP3 between connecting electrodes adjacent to each other among the first to third connecting electrodes CNE1, CNE2, and CNE3 may overlap the separator SPR. For example, the first edges EG11, EG21, and EG31 of the first to third connecting electrodes CNE1, CNE2, and CNE3 may not be covered by the separator SPR, and the second edges EG12, EG22, and EG32 of the first to third connecting electrodes CNE1, CNE2, and CNE3 may overlap the separator SPR. Alternatively, the second edges EG12, EG22, and EG32 of the first to third connecting electrodes CNE1, CNE2, and CNE3 may be covered by the separator SPR.

In an embodiment of the present disclosure, the light emitting connection parts CE3 of the first to third connection parts CNP1, CNP2, and CNP3 may be disposed at positions not overlapping the first to third light emitting parts EPI, EP2, and EP3 when viewed from above the plane. For example, the light emitting opening OP-PDL (refer to FIG. 5) and first through holes OP-P (refer to FIG. 5) spaced apart from the light emitting opening OP-PDL may be defined in the pixel defining layer PDL.

The first though-holes OP-P may include a first-first through hole OP-P1, a first-second through hole OP-P2, and a first-third through hole OP-P3. The first connection part CNP1 and the second connection part CNP2 may be arranged to correspond to the first-first through hole OP-P1 and the first-second through hole OP-P2, respectively, and the light emitting connection part CE3 of the third connection part CNP3 may be arranged to correspond to the first-third through hole OP-P3. The light emitting opening OP-PDL may include a first light emitting opening OP-PDL1, a second light emitting opening OP-PDL2, and a third light emitting opening OP-PDL3. The first to third light emitting parts EPI, EP2, and EP3 may be defined to correspond to the first to third light emitting openings OP-PDL1, OP-PDL2, and OP-PDL3, respectively. Accordingly, the first to third connection parts CNP1, CNP2, and CNP3 may be disposed at positions spaced apart from the first to third light emitting parts EP1, EP2, and EP3.

The first to third connecting electrodes CNE1, CNE2, and CNE3 may be disposed on the pixel defining layer PDL (refer to FIG. 5). When viewed from above the plane, the first connecting electrode CNE1 may surround the first light emitting opening OP-PDL1, the second connecting electrode CNE2 may surround the second light emitting opening OP-PDL2, and the third connecting electrode CNE3 may surround the third light emitting opening OP-PDL3.

According to an embodiment of the present disclosure, the drive connection part CD3 of the third connection part CNP3 where the connecting line CN3 is connected with a transistor TR (refer to FIG. 5) of the third pixel driver PDC3 may be defined at a position not overlapping the light emitting connection part CE3 of the third connection part CNP3 and disposed at a position overlapping the third light emitting part EP3 when viewed from above the plane. The third cathode EL2_3 and the third pixel driver PDC3 may be connected through the connecting line CN3. Accordingly, in the design of the pixel driver PDC3, restrictions depending on the position or shape of the third light emitting part EP3 may be reduced, and thus the degree of freedom in design may be improved. In some embodiments, when viewed from above the plane, the drive connection part CD (refer to FIG. 5) of the first connection part CNP1 where the connecting line CN (refer to FIG. 5) is connected with the transistor TR (refer to FIG. 5) of the first pixel driver PDC1 may be disposed at a position not overlapping the first light emitting part EPI, and the drive connection part CD (refer to FIG. 5) of the second connection part CNP2 where the connecting line CN (refer to FIG. 5) is connected with the transistor TR (refer to FIG. 5) of the second pixel driver PDC2 may be disposed at a position not overlapping the second light emitting part EP2.

The first to third cathodes EL2_1, EL2_2, and EL2_3 may be connected with the first to third connecting electrodes CNE1, CNE2, and CNE3. For example, the lower surfaces of the first to third cathodes EL2_1, EL2_2, and EL2_3 may be connected with (or, brought into contact with) the upper surfaces of the first to third connecting electrodes CNE1, CNE2, and CNE3. Accordingly, the contact reliability (or, connection stability) of the first to third cathodes EL2_1, EL2_2, and EL2_3 and the first to third connecting electrodes CNE1, CNE2, and CNE3 may be further improved.

In some aspects, the connection areas where the first to third cathodes EL2_1, EL2_2, and EL2_3 and the first to third connecting electrodes CNE1, CNE2, and CNE3 are connected may surround at least portions of the first to third light emitting openings OP-PDL1, OP-PDL2, and OP-PDL3. The first to third cathodes EL2_1, EL2_2, and EL2_3 and the first to third connecting electrodes CNE1, CNE2, and CNE3 may be connected in areas adjacent to the separator SPR, and the contact areas may be defined such that the contact areas are adjacent to the separator SPR. That is, the first to third cathodes EL2_1, EL2_2, and EL2_3 and the first to third connecting electrodes CNE1, CNE2, and CNE3 may not be connected at specific points and may be connected over relatively wide areas, for example, areas similar to the shapes of the first to third connecting electrodes CNE1, CNE2, and CNE3. That is, the areas of connection contacts may be increased, and thus the connection may be stably performed.

In FIG. 4D, the separator SPR, the light emitting parts EP1, EP2, and EP3, and a first electrode EL1 are illustrated.

Referring to FIG. 4D, the first electrode EL1 (hereinafter, referred to as the anode) of a light emitting element LD (refer to FIG. 5) according to an embodiment of the present disclosure may be commonly provided for the first to third light emitting parts EP1, EP2, and EP3. That is, the anode EL1 may be formed as one integrated layer in the entire display area DA. Accordingly, the layer of the anode EL1 may be disposed to overlap the separator SPR. Alternatively, the anodes EL1 of the light emitting elements LD may be formed as independent conductive patterns spaced apart from one another and may be electrically connected with one another through another conductive layer. Accordingly, the patterns of the anodes EL1 may be disposed so as not to overlap the separator SPR.

As described herein, the first power supply voltage VDD (refer to FIG. 2A) may be applied to the anode EL1, and a common voltage may be provided to all of the light emitting parts. The anode EL1 may be connected with the first power line VDL (refer to FIG. 2A), which provides the first power supply voltage VDD, in the peripheral area NDA or may be connected with the first power line VDL (refer to FIG. 2A) in the display area DA and is not limited to any one embodiment.

A plurality of openings may be defined in the anode EL1 according to this embodiment. The openings may penetrate the layer of the anode EL1. The openings in the layer of the anode EL1 may be disposed at positions not overlapping the light emitting parts EP (refer to FIG. 3A) and may be defined at positions overlapping the separator SPR. The openings may facilitate releasing gas generated from an organic layer disposed under the anode EL1, for example, a sixth insulating layer 60 (refer to FIG. 5) that will be described herein. Accordingly, the gas of the organic layer disposed under the light emitting element may be sufficiently released in the process of manufacturing the display panel, and gas released from the organic layer after the manufacture of the display panel may be reduced. Thus, the speed at which the light emitting element is degraded may be decreased.

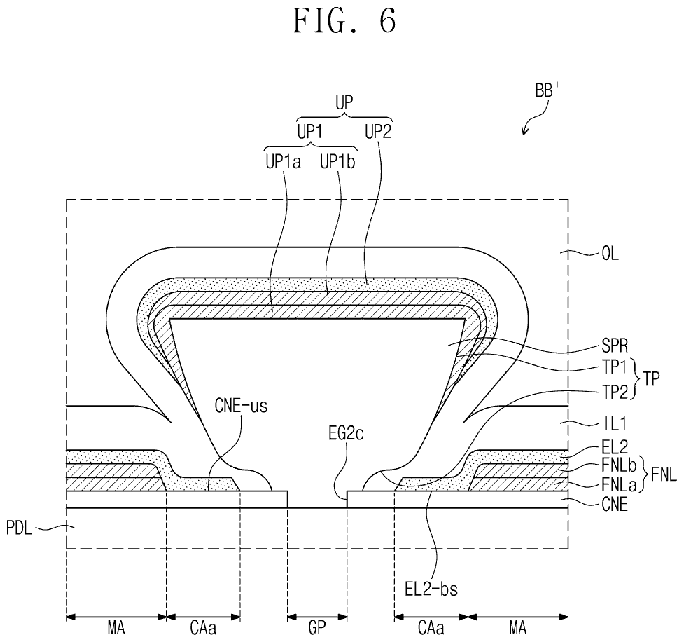

FIG. 5 is a sectional view of the display panel DP according to an embodiment of the present disclosure. FIG. 6 is an enlarged sectional view of a partial area of the display panel DP according to an embodiment of the present disclosure. FIG. 7 is an enlarged sectional view of a partial area of the display panel DP according to an embodiment of the present disclosure. FIG. 5 illustrates a sectional view illustrating a portion corresponding to line I-I′ of FIG. 4A. FIG. 6 illustrates an enlarged sectional view of area AA′ of FIG. 5. FIG. 7 illustrates an enlarged sectional view of area BB′ of FIG. 5.

Referring to FIGS. 5 to 7, the display panel DP of an embodiment may include a base layer BS, a drive element layer DDL, a connecting line CN, a light emitting element layer LDL, an encapsulation layer ECL, and a sensing layer ISL. However, this is an example, and in an embodiment of the present disclosure, the display panel DP may not include the sensing layer ISL.

The drive element layer DDL may include a plurality of insulating layers 10, 20, 30, 40, 50, and 60 disposed on the base layer BS and a plurality of conductive patterns and semiconductor patterns disposed between the insulating layers 10, 20, 30, 40, 50, and 60. The conductive patterns and the semiconductor patterns may be disposed between the insulating layers 10, 20, 30, 40, 50, and 60 to constitute a pixel driver PDC. In FIG. 5, for ease of description, a cross-section of a partial region of an area in which one light emitting part is disposed is illustrated.

The base layer BS may be a member that provides a base surface on which the pixel driver PDC is disposed. The base layer BS may be a rigid substrate or may be a flexible substrate capable of being bent, folded, or rolled. The base layer BS may be a glass substrate, a metal substrate, or a polymer substrate. However, embodiments of the present disclosure are not limited thereto, and the base layer BS may be an inorganic layer, an organic layer, or a composite layer.

The base layer BS may have a multilayer structure. The base layer BS may include a first polymer resin layer, a silicon oxide (SiOx) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. Alternatively, the polymer resin layer may include at least one of an acrylic resin, a methacrylic resin, a polyisoprene resin, a vinyl resin, an epoxy resin, a urethane-based resin, a cellulosic resin, a siloxane-based resin, a polyamide resin, and a perylene-based resin. A “˜˜”-based resin used herein means a resin containing a “˜˜” functional group.

Insulating layers, conductive layers, and semiconductor layers disposed on the base layer BS may be formed by a method such as, for example, coating or deposition. Thereafter, the insulating layers, the semiconductor layers, and the conductive layers may be selectively subjected to patterning by performing a photolithography process a plurality of times. Accordingly, holes may be formed in the insulating layers, or a semiconductor pattern, a conductive pattern, and a signal line may be formed on the insulating layers.

The drive element layer DDL may include the first to sixth insulating layers 10, 20, 30, 40, 50, and 60 sequentially stacked on the base layer BS and the pixel driver PDC. One transistor TR and two capacitors C1 and C2 of the pixel driver PDC are illustrated in FIG. 5. In this specification, the fifth insulating layer 50 may be referred to as a lower insulating layer, and the sixth insulating layer 60 may be referred to as an intermediate insulating layer.

The transistor TR may correspond to a transistor connected to a light emitting element LD through the connecting line CN and a connecting electrode CNE, that is, a connection transistor connected to a node (the fourth node N4 of FIG. 2A, the second node N2 of FIG. 2B, or the fourth node N4 of FIG. 2C) that corresponds to a cathode of the light emitting element LD. Specifically, the transistor TR may correspond to the sixth transistor T6 of FIG. 2A, the first transistor T1 of FIG. 2B, or the fourth transistor T4a of FIG. 2C. In some embodiments, although not illustrated, other transistors constituting the pixel driver PDC may have the same structure as the transistor TR (hereinafter, referred to as the connection transistor) illustrated in FIG. 5. However, this is illustrative, and the other transistors constituting the pixel driver PDC may have a structure different from the structure of the connection transistor TR and are not limited to any one embodiment.

The first insulating layer 10 may be disposed on the base layer BS. The first insulating layer 10 may be an inorganic layer and/or an organic layer and may have a single-layer structure or a multilayer structure. The first insulating layer 10 may include at least one of aluminum oxide, titanium oxide, silicon oxide, silicon nitride, silicon oxy nitride, zirconium oxide, and hafnium oxide. In this embodiment, the first insulating layer 10 is illustrated as a single silicon oxide layer. In some embodiments, the insulating layers to be described herein may be inorganic layers and/or organic layers and may have a single-layer structure or a multilayer structure. The inorganic layers may include at least one of the aforementioned materials, but are not limited thereto.

In some aspects, the first insulating layer 10 may cover a lower conductive layer BCL. That is, the display panel DP may further include the lower conductive layer BCL disposed to overlap the connection transistor TR. The lower conductive layer BCL may block an influence of an electrical potential due to a polarization phenomenon of the base layer BS on the connection transistor TR. In some aspects, the lower conductive layer BCL may block light incident to the connection transistor TR from below. At least one of an inorganic barrier layer and a buffer layer may be additionally disposed between the lower conductive layer BCL and the base layer BS.

The lower conductive layer BCL may include reflective metal. For example, the lower conductive layer BCL may include titanium (TI), molybdenum (Mo), an alloy containing molybdenum, aluminum (Al), an alloy containing aluminum, aluminum nitride (AlN), tungsten (W), tungsten nitride (WN), and copper (Cu).

In this embodiment, the lower conductive layer BCL may be connected with a source of the connection transistor TR (or, the transistor) through a source electrode pattern W1. In this case, the lower conductive layer BCL may be synchronized with the source of the transistor TR. However, this is illustrative, and the lower conductive layer BCL may be connected to a gate of the transistor TR and may be synchronized with the gate. Alternatively, the lower conductive layer BCL may be connected to another electrode and may independently receive a constant voltage or a pulse signal. In another case, the lower conductive layer BCL may be provided in a form isolated from another conductive pattern. The lower conductive layer BCL according to an embodiment of the present disclosure may be provided in various forms and is not limited to any one embodiment.

The connection transistor TR may be disposed on the first insulating layer 10. The connection transistor TR may include a semiconductor pattern SP and a gate electrode GE. The semiconductor pattern SP may be disposed on the first insulating layer 10. The semiconductor pattern SP may include an oxide semiconductor. For example, the oxide semiconductor may include transparent conductive oxide (TCO) such as, for example, indium tin oxide (ITO), indium zinc oxide (IZO), indium gallium zinc oxide (IGZO), zinc oxide (ZnO), or indium oxide (In₂O₃). However, without being limited thereto, the semiconductor pattern SP may include amorphous silicon, low-temperature polycrystalline silicon, or polycrystalline silicon.

The semiconductor pattern SP may include a source area SR, a drain area DR, and a channel area CR distinguished from one another depending on the degree of conductivity. The channel area CR may be a portion overlapping the gate electrode GE when viewed from above the plane. The source area SR and the drain area DR may be portions spaced apart from each other with the channel area CR between the source area SR and the drain area DR. In an example in which the semiconductor pattern SP is an oxide semiconductor, the source area SR and the drain area DR may be reduced areas. Accordingly, the source area SR and the drain area DR may have a higher reduced-metal content than the channel area CR. Alternatively, when the semiconductor pattern SP is polycrystalline silicon, the source area SR and the drain area DR may be highly doped areas.

The source area SR and the drain area DR may have a higher conductivity than the channel area CR. The source area SR may correspond to the source electrode of the connection transistor TR, and the drain area DR may correspond to the drain electrode of the connection transistor TR. As illustrated in FIG. 5, the source electrode pattern W1 and a drain electrode pattern W2 connected to the source area SR and the drain area DR, respectively, may be further included. Specifically, the source electrode pattern W1 and the drain electrode pattern W2 may be integrally formed with one of lines constituting the pixel driver (refer to PDC of FIG. 2A, PDC-1 of FIG. 2B, or PDC-2 of FIG. 2C) and are not limited to any one embodiment.

The second insulating layer 20 may commonly overlap a plurality of pixels and may cover the semiconductor pattern SP. The second insulating layer 20 may be an inorganic layer and/or an organic layer and may have a single-layer structure or a multilayer structure. The second insulating layer 20 may include at least one of aluminum oxide, titanium oxide, silicon oxide, silicon nitride, silicon oxy nitride, zirconium oxide, and hafnium oxide. In this embodiment, the second insulating layer 20 may be a single silicon oxide layer.

The gate electrode GE may be disposed on the second insulating layer 20. The gate electrode GE may correspond to the gate of the connection transistor TR. In some aspects, the gate electrode GE may be disposed over the semiconductor pattern SP. However, this is illustrative, and the gate electrode GE may be disposed under the semiconductor pattern SP and is not limited to any one embodiment.

The gate electrode GE may include titanium (TI), silver (Ag), molybdenum (Mo), aluminum (Al), aluminum nitride (AlN), tungsten (W), tungsten nitride (WN), copper (Cu), or an alloy thereof, but is not particularly limited thereto.

The third insulating layer 30 may be disposed on the gate electrode GE. The third insulating layer 30 may be an inorganic layer and/or an organic layer and may have a single-layer structure or a multilayer structure. The fourth insulating layer 40 may include at least one of aluminum oxide, titanium oxide, silicon oxide, silicon nitride, silicon oxy nitride, zirconium oxide, and hafnium oxide.

Among a plurality of conductive patterns W1, W2, CPE1, CPE2, and CPE3, the first capacitor electrode CPE1 and the second capacitor electrode CPE2 constitute the first capacitor C1. The first capacitor electrode CPE1 and the second capacitor electrode CPE2 may be spaced apart from each other with the first insulating layer 10 and the second insulating layer 20 between the first capacitor electrode CPE1 and the second capacitor electrode CPE2.

In an embodiment of the present disclosure, the first capacitor electrode CPE1 and the lower conductive layer BCL may have a one-body shape. In some aspects, the second capacitor electrode CPE2 and the gate electrode GE may have a one-body shape.

The third capacitor electrode CPE3 may be disposed on the third insulating layer 30. The third capacitor electrode CPE3 may be spaced apart from the second capacitor electrode CPE2 with the third insulating layer 30 between the third capacitor electrode CPE3 and the second capacitor electrode CPE2. The third capacitor electrode CPE3 and the second capacitor electrode CPE2 may overlap the second capacitor electrode CPE2 when viewed from above the plane. The third capacitor electrode CPE3, together with the second capacitor electrode CPE2, may constitute the second capacitor C2.

The fourth insulating layer 40 may be disposed on the third insulating layer 30 and/or the third capacitor electrode CPE3. The fourth insulating layer 40 may be an inorganic layer and/or an organic layer and may have a single-layer structure or a multilayer structure. The fourth insulating layer 40 may include at least one of aluminum oxide, titanium oxide, silicon oxide, silicon nitride, silicon oxy nitride, zirconium oxide, and hafnium oxide.

The source electrode pattern W1 and the drain electrode pattern W2 may be disposed on the fourth insulating layer 40. The source electrode pattern W1 may be connected to the source area SR of the connection transistor TR through a first contact hole CNT1, and the source electrode pattern W1 and the source area SR of the semiconductor pattern SP may function as the source of the connection transistor TR. The drain electrode pattern W2 may be connected to the drain area DR of the connection transistor TR through a second contact hole CNT2, and the drain electrode pattern W2 and the drain area DR of the semiconductor pattern SP may function as the drain of the connection transistor TR. The fifth insulating layer 50 may be disposed on the source electrode pattern W1 and the drain electrode pattern W2.

The connecting line CN may be disposed on the fifth insulating layer 50. The connecting line CN may electrically connect the pixel driver PDC and the light emitting element LD. That is, the connecting line CN may electrically connect the connection transistor TR and the light emitting element LD. The connecting line CN may be a connection node that connects the pixel driver PDC and the light emitting element LD. That is, the connecting line CN may correspond to the fourth node N4 (refer to FIG. 2A) illustrated in FIG. 2A, may correspond to the second node N2 (refer to FIG. 2B) illustrated in FIG. 2B, or may correspond to the fourth node N4 (refer to FIG. 2C) illustrated in FIG. 2C.

The connecting line CN of FIG. 5 may correspond to a connecting line that electrically connects the first pixel driver PDC1 (refer to FIG. 4B) and the first light emitting element LD1 (refer to FIG. 4C). However, the connecting line that electrically connects the second pixel driver PDC2 (refer to FIG. 4B) and the second light emitting element LD2 (refer to FIG. 4C) and the connecting line CN3 (refer to FIG. 4A) that electrically connects the third pixel driver PDC3 (refer to FIG. 4B) and the third light emitting element LD3 (refer to FIG. 4C) may also have a structure similar to the structure of the connecting line CN of FIG. 5.

The sixth insulating layer 60 may be disposed on the connecting line CN. The sixth insulating layer 60 may be disposed on the fifth insulating layer 50 and may cover at least a portion of the connecting line CN. Each of the fifth insulating layer 50 and the sixth insulating layer 60 may be an organic layer. For example, each of the fifth insulating layer 50 and the sixth insulating layer 60 may include a general purpose polymer, such as, for example, benzocyclobutene (BCB), polyimide, hexamethyldisiloxane (HMDSO), Polymethylmethacrylate (PMMA), or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a blend thereof.

The sixth insulating layer 60 may have a second through hole OP-60 formed therein to expose at least a portion of the connecting line CN. The connecting line CN may be connected to the connecting electrode CNE through a portion exposed from the sixth insulating layer 60 and may be electrically connected with the light emitting element LD. That is, the connecting line CN, together with the connecting electrode CNE, may electrically connect the connection transistor TR and the light emitting element LD. In this specification, the area where the connecting line CN and the connecting electrode CNE are connected may be referred to as a connection area CNA. The connection area CNA may be defined in the second through hole OP-60. In the display panel DP according to an embodiment of the present disclosure, the sixth insulating layer 60 may be omitted, or a plurality of sixth insulating layers 60 may be provided. However, the present disclosure is not limited to any one embodiment.

The light emitting element layer LDL may be disposed on the drive element layer DDL. The light emitting element layer LDL may include a pixel defining layer PDL, the light emitting element LD, and a separator SPR.

The pixel defining layer PDL may be an organic layer. For example, the pixel defining layer PDL may include a general purpose polymer, such as, for example, benzocyclobutene (BCB), polyimide, hexamethyldisiloxane (HMDSO), Polymethylmethacrylate (PMMA), or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a blend thereof.

In an embodiment, the pixel defining layer PDL may have a property of absorbing light. For example, the pixel defining layer PDL may be black in color. That is, the pixel defining layer PDL may include a black coloring agent. The black coloring agent may include a black dye or a black pigment. The black coloring agent may include carbon black, metal such as, for example, chromium, or oxide thereof. The pixel defining layer PDL may correspond to a light blocking pattern having light-blocking characteristics.

An opening OP-PDL (hereinafter, referred to as the light emitting opening) for exposing at least a portion of a first electrode EL1 that will be described herein may be defined in the pixel defining layer PDL. A plurality of light emitting openings OP-PDL may be provided. The plurality of light emitting openings OP-PDL may be disposed to correspond to light emitting elements, respectively. All components of the light emitting element LD may be disposed in the light emitting opening OP-PDL to overlap one another, and the light emitting opening OP-PDL may be an area where light emitted by the light emitting element LD is substantially displayed. Accordingly, the shape of the first light emitting part EP1 (refer to FIG. 4A) may substantially correspond to the shape of the light emitting opening OP-PDL when viewed from above the plane. The area corresponding to the first light emitting part EP1, that is, the area defined by the light emitting opening OP-PDL may be referred to as an emissive area EA.

The connecting electrode CNE may be disposed on the pixel defining layer PDL. The connecting electrode CNE may electrically connect the pixel driver PDC and the light emitting element LD. That is, the pixel driver PDC may be electrically connected to the light emitting element LD through the connecting line CN and the connecting electrode CNE. The connecting electrode CNE may correspond to the first connecting electrode CNE1 illustrated in FIG. 4A. The second connecting electrode CNE2 (refer to FIG. 4A) and the third connecting electrode CNE3 (refer to FIG. 4A) may also have a structure similar to the structure of the connecting electrode CNE.

The connecting electrode CNE may include a first edge EG1c adjacent to the light emitting opening OP-PDL and a second edge EG2c surrounding the first edge EG1c. A second electrode EL2 of the light emitting element LD may be brought into contact with the connecting electrode CNE in an area adjacent to the second edge EG2c.

The connecting electrode CNE may include transparent conductive oxide (TCO) such as, for example, indium tin oxide (ITO), indium zinc oxide (IZO), indium gallium zinc oxide (IGZO), zinc oxide (ZnOx), or indium oxide (In₂O₃). However, the material of the connecting electrode CNE is not limited to the aforementioned examples. For example, the connecting electrode CNE may include a metallic material.

A first through hole OP-P spaced apart from the light emitting opening OP-PDL may be defined in the pixel defining layer PDL. A plurality of first through holes OP-P may be provided. The plurality of first through holes OP-P may be disposed to correspond to light emitting elements, respectively. The size of the first through hole OP-P defined in the pixel defining layer PDL may be greater than the size of the second through hole OP-60 defined in the sixth insulating layer 60. The connecting electrode CNE may be disposed in the first through hole OP-P and the second through hole OP-60 and may be connected with the connecting line CN.

The light emitting element LD may include the first electrode EL1, an intermediate layer IML, and the second electrode EL2.

The first electrode EL1 may be a transflective electrode, a transmissive electrode, or a reflective electrode. According to an embodiment of the present disclosure, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof and a transparent or translucent electrode layer formed on the reflective layer. The transparent or translucent electrode layer may include at least one selected from the group consisting of indium tin oxide (ITO), indium zinc oxide (IZO), indium gallium zinc oxide (IGZO), zinc oxide (ZnO), or indium oxide (In₂O₃) and aluminum-doped zinc oxide (AZO). For example, the first electrode EL1 may include a stacked structure of ITO/Ag/ITO.

In this embodiment, the first electrode EL1 may be an anode of the light emitting element LD. That is, the first electrode EL1 may be connected with the first power line VDL (refer to FIG. 2A) and may receive the first power supply voltage VDD (refer to FIG. 2A). The first electrode EL1 may be connected with the first power line VDL in the display area DA (refer to FIG. 3A or 3B) or may be connected with the first power line VDL in the peripheral area NDA. In the latter case, the first power line VDL may be disposed in the peripheral area NDA (refer to FIG. 3A or 3B), and the first electrode EL1 may have a shape extending to the peripheral area NDA.

In the sectional view of FIG. 5, the first electrode EL1 is illustrated as overlapping the light emitting opening OP-PDL and not overlapping the separator SPR. However, as described herein with reference to FIG. 4D, the first electrodes EL1 of the light emitting elements may have a one-body shape and may have a mesh or grid shape in which openings are defined in a partial area. That is, as long as the same first power supply voltage VDD is capable of being applied to the first electrodes EL1 of the plurality of light emitting elements, the shape of the first electrode EL1 may be provided in various ways and is not limited to any one embodiment.

The intermediate layer IML may be disposed between the first electrode EL1 and the second electrode EL2. The intermediate layer IML may include an emissive layer EML and a functional layer FNL. The light emitting element LD may include the intermediate layer IML having various structures and is not limited to any one embodiment. For example, the functional layer FNL may include a plurality of layers or may include two or more layers spaced apart from each other with the emissive layer EML between the two or more layers.

Referring to FIGS. 5 and 6, the functional layer FNL may be disposed between the first electrode EL1 and the second electrode EL2. The functional layer FNL may include a first intermediate functional layer FNLa disposed between the first electrode EL1 and the emissive layer EML and a second intermediate functional layer FNLb disposed between the second electrode EL2 and the emissive layer EML. In this embodiment, the emissive layer EML is illustrated as being inserted into the functional layer FNL. That is, it may be understood that the emissive layer EML is disposed between the first intermediate functional layer FNLa and the second intermediate functional layer FNLb.

The functional layer FNL may control the movement of charges between the first electrode EL1 and the second electrode EL2. For example, the first intermediate functional layer FNLa may include a hole injection/transport material and/or an electron injection/transport material. The second intermediate functional layer FNLb may include at least one of an electron blocking layer, a hole transport layer, a hole injection layer, a hole blocking layer, an electron transport layer, an electron injection layer, and a charge generation layer.

The emissive layer EML may include an organic luminescent material. Alternatively, the emissive layer EML may include an inorganic luminescent material or may be provided as a mixed layer of an organic luminescent material and an inorganic luminescent material. In this embodiment, the emissive layers EML included in the adjacent light emitting parts EP (refer to FIG. 3A) may include luminescent materials that display different colors. For example, the emissive layer EML included in each of the light emitting parts EP may provide one of red light, green light, and blue light. However, without being limited thereto, the emissive layers EML disposed in all of the light emitting parts EP may include a luminescent material that displays the same color. In this case, the emissive layers EML may provide blue light or white light.

The second electrode EL2 may be disposed on the intermediate layer IML. As described herein, the second electrode EL2 may be connected to the connecting electrode CNE and may be electrically connected to the pixel driver PDC. That is, the second electrode EL2 may be electrically connected with the connection transistor TR through the connecting electrode CNE.

The separator SPR may be disposed on the pixel defining layer PDL. In some aspects, the separator SPR may be disposed over the gap GP between the connecting electrode CNE disposed on the pixel defining layer PDL and an adjacent connecting electrode adjacent to the connecting electrode CNE.

In an embodiment, the second electrode EL2 and the functional layer FNL may be commonly formed for the plurality of pixels by deposition through an open mask. In this case, the second electrode EL2 and the functional layer FNL may be divided from each other by the separator SPR. As described herein, the separator SPR may have a closed-line shape for each of the light emitting parts, and thus the second electrode EL2 and the functional layer FNL may have a divided shape for each light emitting part. That is, the second electrode EL2 and the intermediate layer IML may be electrically independent for respective adjacent pixels.

In an embodiment, the separator SPR may have an inverted tapered shape. That is, the separator SPR may have a shape in which the width is increased farther away from the upper surface of the pixel defining layer PDL. A side surface TP of the separator SPR may have a shape in which a taper angle inclined with respect to the upper surface of the pixel defining layer PDL is an obtuse angle. However, this is illustrative, and as long as the separator SPR is capable of electrically disconnecting the second electrode EL2 for each pixel, the taper angle of the separator SPR may be set in various ways. For example, the separator SPR may have a dual structure with different taper angles. In some aspects, the separator SPR may have a structure such as, for example, a tip portion and is not limited to any one embodiment.

As illustrated in FIGS. 5 and 6, the separator SPR may have a dual inverted tapered shape. The side surface TP of the separator SPR may include a first side surface TP1 and a second side surface TP2 that have different taper angles. The taper angle formed by the first side surface TP1 of the separator SPR with respect to the upper surface of the pixel defining layer PDL may be different from the taper angle formed by the second side surface TP2 of the separator SPR with respect to the upper surface of the pixel defining layer PDL. The taper angles may be obtuse angles. For example, as illustrated in FIG. 6, the taper angle formed by the first side surface TP1 with respect to the upper surface of the pixel defining layer PDL may be smaller than the taper angle formed by the second side surface TP2 with respect to the upper surface of the pixel defining layer PDL. However, this is illustrative, and the taper angles may be set in various ways as long as the separator SPR is capable of electrically disconnecting the second electrode EL2 for each pixel. In some aspects, the separator SPR may have a structure such as, for example, a tip portion and is not limited to any one embodiment.

The separator SPR may include an insulating material. In particular, the separator SPR may include an organic insulating material. Alternatively, the separator SPR may include an inorganic insulating material. In another case, the separator SPR may be constituted by multiple layers of an organic insulating material and an inorganic insulating material. In some embodiments, the separator SPR may include a conductive material. That is, the type of material of the separator SPR is not particularly limited as long as the separator SPR is capable of electrically disconnecting the second electrode EL2 for each pixel.

A dummy layer UP may be disposed on the separator SPR. The dummy layer UP may include a first dummy layer UPI disposed on the separator SPR and a second dummy layer UP2 disposed on the first dummy layer UP1. The first dummy layer UPI may be formed through the same process as the intermediate layer IML and may include the same material as the intermediate layer IML. The first dummy layer UP1 may include a first-first dummy layer UP1a and a first-second dummy layer UP1b. The first-first dummy layer UP1a may be formed through the same process as the first intermediate functional layer FNLa and may include the same material as the first intermediate functional layer FNLa. The first-second dummy layer UP1b may be formed through the same process as the second intermediate functional layer FNLb and may include the same material as the second intermediate functional layer FNLb. The second dummy layer UP2 may be formed through the same process as the second electrode EL2 and may include the same material as the second electrode EL2. That is, the first dummy layer UP1 and the second dummy layer UP2 may be simultaneously formed in the process of forming the functional layer FNL and the second electrode EL2. As illustrated in FIG. 6, the dummy layer UP may be formed not only on the upper surface of the separator SPR but also on a portion of the side surface TP of the separator SPR. In an embodiment, the display panel DP may not include the dummy layer UP. The dummy layer UP may not be in contact with the connecting electrode CNE and the second electrode EL2. The second dummy layer UP2 included in the dummy layer UP may not be in contact with the connecting electrode CNE and the second electrode EL2.

The second electrode EL2 is brought into contact with the connecting electrode CNE through a contact area CA. The contact area CA may include a first contact area CAa and a second contact area CAb. The first contact area CAa is provided adjacent to the separator SPR. The second contact area CAb is provided adjacent to the side surface of the connecting line CN exposed by the first through hole OP-P and the second through hole OP-60. Detailed description of the second contact area CAb will be given below. Hereinafter, the first contact area CAa will be described in detail with reference to FIGS. 5 and 6.

In the first contact area CAa, the upper surface CNE-us of the connecting electrode CNE is brought into contact with the lower surface EL2-bs of the second electrode EL2. In some embodiments, since the separator SPR has an inverted tapered shape and the first contact area CAa is provided adjacent to (e.g., relatively near, within a target distance of) the separator SPR, at least a portion of the first contact area CAa where the second electrode EL2 and the connecting electrode CNE are brought into contact with each other may be disposed under the side surface TP of the separator SPR. The first contact area CAa, when viewed from above the plane, may have a ring shape surrounding at least a portion of the light emitting opening OP-PDL of the pixel defining layer PDL.

In some embodiments, at least a portion of the connecting electrode CNE may be disposed under the separator SPR. The separator SPR may be disposed over the gap GP between the connecting electrode CNE and the adjacent connecting electrode adjacent to the connecting electrode CNE, and the second edge EG2c of the second electrode EL2 may be covered by the separator SPR.

The display panel DP of an embodiment may include an intermediate area MA disposed between the emissive area EA in which the light emitting element LD is disposed and the first contact area CAa. The intermediate area MA may be an area in which at least a portion of the intermediate layer IML is disposed. In the intermediate area MA, the functional layer FNL included in the intermediate layer IML may be disposed between the connecting electrode CNE and the second electrode EL2. That is, in the intermediate area MA, the connecting electrode CNE and the second electrode EL2 may be spaced apart from each other with the functional layer FNL between the connecting electrode CNE and the second electrode EL2.

The intermediate area MA may be adjacent to the first contact area CAa. The functional layer FNL disposed in the intermediate area MA may include the first intermediate functional layer FNLa and the second intermediate functional layer FNLb described herein. The first intermediate functional layer FNLa may be disposed between the first electrode EL1 and the emissive layer EML in the emissive area EA, and the second intermediate functional layer FNLb may be disposed between the second electrode EL2 and the emissive layer EML in the emissive area EA.

In the display panel DP of an embodiment, the functional layer FNL and the second electrode EL2 may be formed through different deposition processes. The second electrode EL2 may be formed by a deposition method that deposits a deposition material at a low incidence angle when compared to a deposition method that forms the functional layer FNL. For example, the functional layer FNL may be formed using a thermal evaporation method, and the second electrode EL2 may be covered using a sputtering method. Accordingly, in the process of forming the functional layer FNL, the material that forms the functional layer FNL may fail to enter below the side surface TP of the separator SPR, and therefore a portion of the connecting electrode CNE may be exposed. The second electrode EL2 may be formed closer to the separator SPR than the functional layer FNL and may be in contact with the upper surface CNE-us of the connecting electrode CNE on which the second electrode EL2 is exposed. That is, the first contact area CAa where the second electrode EL2 and the connecting electrode CNE are in contact with each other may be formed through the difference between the deposition methods in the process of forming the functional layer FNL and the second electrode EL2.

In some embodiments, as illustrated in FIG. 5, the connection area CNA where the connecting electrode CNE is connected to the connecting line CN may be disposed between the emissive area EA and the first contact area CAa. The connection area CNA may overlap the intermediate area MA. At least a portion of the intermediate layer IML may be disposed to overlap the connection area CNA. In the display panel DP of an embodiment, the functional layer FNL included in the intermediate layer IML may be disposed to overlap the connection area CNA.

According to an embodiment of the present disclosure, the connecting electrode CNE has a shape surrounding at least a portion of the emissive area EA where the light emitting element LD is disposed. Accordingly, the degree of freedom in the position where the connecting electrode CNE and the light emitting element LD are connected and the degree of freedom in the position where the connecting electrode CNE and the pixel driver PDC are connected may be improved. In some aspects, the upper surface CNE-us of the connecting electrode CNE may be brought into contact with the lower surface EL2-bs of the second electrode EL2 of the light emitting element LD through the first contact area CAa defined adjacent to the separator SPR. Accordingly, the contact reliability of the connecting electrode CNE and the second electrode EL2 may be improved, and since the lower surface of the connecting electrode CNE and the upper surface of the connecting line CN are brought into contact with each other, the contact reliability may be improved. In the display panel DP according to an embodiment, the sizes of the first through hole OP-P and the second through hole OP-60 for connecting the connecting electrode CNE and the connecting line CN may be decreased or minimized through the structure described herein, and thus the area or resolution of the light emitting part of the display panel DP may be easily increased.

As illustrated in FIGS. 5 and 7, the connecting electrode CNE may be electrically connected to the pixel driver PDC through the connecting line CN. As described herein, the connecting line CN may include the drive connection part CD and the light emitting connection part CE. The drive connection part CD may be a part of the connecting line CN connected with the pixel driver PDC and may be a part substantially connected with the connection transistor TR. In this embodiment, the drive connection part CD may be connected to the drain electrode pattern W2 through a contact hole penetrating the fifth insulating layer 50 and may be electrically connected to the drain area DR of the semiconductor pattern SP through the drain electrode pattern W2. The light emitting connection part CE may be a part of the connecting line CN connected with the connecting electrode CNE. The light emitting connection part CE may be a part that is defined in an area exposed from the sixth insulating layer 60 and to which the connecting electrode CNE is connected. In this case, a tip portion TIP may be defined on the light emitting connection part CE.

The light emitting connection part CE of the connecting line CN will be described herein in more detail with reference to FIGS. 5 and 7. As illustrated in FIGS. 5 and 7, the connecting line CN may have a three-layer structure. The tip portion TIP may be defined on at least a portion of an edge of the connecting line CN. The edge of the connecting line CN where the tip portion TIP is defined may correspond to a portion of the edge of the connecting line CN exposed from the sixth insulating layer 60 and the pixel defining layer PDL by the first through hole OP-P and the second through hole OP-60. In other words, the first through hole OP-P and the second through hole OP-60 may expose the tip portion TIP of the connecting line CN from the sixth insulating layer 60 and the pixel defining layer PDL.

Specifically, the connecting line CN may include a first layer L1, a second layer L2, and a third layer L3 sequentially stacked in the third direction DR3. A side surface CN_W of the connecting line CN may include a side surface L1_W of the first layer L1, a side surface L2_W of the second layer L2, and a side surface L3_W of the third layer 13.

The second layer L2 may include a material different from a material of the first layer L1. In some aspects, the second layer L2 may include a material different from a material of the third layer L3. The second layer L2 may have a greater thickness than the first layer Li. In some aspects, the second layer L2 may have a greater thickness than the third layer L3. The second layer L2 may include a highly conductive material. In an embodiment, the second layer L2 may include aluminum (Al).

In some embodiments, the first layer Li may include a material having a lower etch rate than the second layer L2. That is, the second layer L2 may be formed of materials having a high etch selectivity with respect to the first layer Li. In an embodiment, the first layer Li may include titanium (Ti), and the second layer L2 may include aluminum (Al). In this case, the side surface L1_W of the first layer L1 may be defined outward of the side surface L2_W of the second layer L2. That is, the light emitting connection part CE of the connecting line CN may have a shape in which the side surface L1_W of the first layer Li protrudes outward from the side surface L2_W of the second layer L2. That is, the light emitting connection part CE of the connecting line CN may have a shape in which the side surface L2_W of the second layer L2 is recessed inward from the side surface L1_W of the first layer Li.

In some aspects, the third layer L3 may include a material having a lower etch rate than the second layer L2. That is, the third layer L3 and the second layer L2 may be formed of materials with high etch selectivity. In an embodiment, the third layer L3 may include titanium (Ti), and the second layer L2 may include aluminum (Al). In this case, the side surface L3_W of the third layer L3 may be defined outward of the side surface L2_W of the second layer L2. That is, the light emitting connection part CE of the connecting line CN may have a shape in which the side surface L3_W of the third layer L3 protrudes outward from the side surface L2_W of the second layer L2. That is, the light emitting connection part CE of the connecting line CN may have an undercut shape or an overhang structure, and the tip portion TIP may be defined on the connecting line CN by the portion of the third layer L3 that protrudes relative to the second layer L2.

The sixth insulating layer 60 and the pixel defining layer PDL may expose at least a portion of the tip portion TIP and at least a portion of the side surface L2_W of the second layer L2. Specifically, the second through hole OP-60 exposing one side of the connecting line CN may be defined in the sixth insulating layer 60, and the first through hole OP-P overlapping the second through hole OP-60 may be defined in the pixel defining layer PDL. The planar area of the first through hole OP-P may be greater than the planar area of the second through hole OP-60. However, embodiments of the present disclosure are not limited thereto, and the planar area of the first through hole OP-P may be smaller than or equal to the planar area of the second through hole OP-60 as long as at least a portion of the tip portion TIP and at least a portion of the side surface L2_W are capable of being exposed.

The connecting electrode CNE may be disposed on the pixel defining layer PDL. The connecting electrode CNE may also be disposed on a partial area of the sixth insulating layer 60 exposed by the first through hole OP-P of the pixel defining layer PDL. In some aspects, the connecting electrode CNE may also be disposed on a partial area of the connecting line CN exposed by the second through hole OP-60 of the sixth insulating layer 60. As illustrated in FIG. 7, the connecting electrode CNE may include an end portion CEN1 disposed along the upper surface of the fifth insulating layer 50 and an opposite end portion CEN2 disposed along the upper surface of the connecting line CN that defines the tip portion TIP. That is, when viewed on the cross-section, the connecting electrode CNE may have a shape that is partially disconnected with respect to the tip portion TIP in the area where the light emitting connection part CE is defined. However, when viewed from above the plane, the connecting electrode CNE may have a one-body shape that is connected as a whole within the area (refer to FIG. 4) defined as a closed line by the separator SPR.

The intermediate layer IML may be disposed on the connecting electrode CNE. The intermediate layer IML may also be disposed on a partial area of the sixth insulating layer 60 exposed by the first through hole OP-P of the pixel defining layer PDL. In some aspects, the intermediate layer IML may also be disposed on a partial area of the connecting line CN exposed by the second through hole OP-60 of the sixth insulating layer 60. As illustrated in FIG. 7, the intermediate layer IML may include an end portion IN1 disposed along the upper surface of the fifth insulating layer 50 and an opposite end portion IN2 disposed along the upper surface of the connecting line CN that defines the tip portion TIP. That is, when viewed on the cross-section, the intermediate layer IML may have a shape that is partially disconnected with respect to the tip portion TIP in the area where the light emitting connection part CE is defined. However, when viewed from above the plane, the intermediate layer IML may have a one-body shape that is connected as a whole within the area (refer to FIG. 4) defined as a closed line by the separator SPR.

The second electrode EL2 may be disposed on the intermediate layer IML. The second electrode EL2 may also be disposed on a partial area of the sixth insulating layer 60 exposed by the first through hole OP-P of the pixel defining layer PDL. In some aspects, the second electrode EL2 may also be disposed on a partial area of the connecting line CN exposed by the second through hole OP-60 of the sixth insulating layer 60. As illustrated in FIG. 7, the second electrode EL2 may include an end portion EN1 of the second electrode EL2 disposed along the upper surface of the fifth insulating layer 50 and an opposite end portion EN2 disposed along the upper surface of the connecting line CN that defines the tip portion TIP. That is, when viewed on the cross-section, the second electrode EL2 may have a shape that is partially disconnected with respect to the tip portion TIP in the area where the light emitting connection part CE is defined. However, when viewed from above the plane, the second electrode EL2 may have a one-body shape that is connected as a whole within the area (refer to FIG. 4) defined as a closed line by the separator SPR.

The end portion CEN1 of the connecting electrode CNE may be disposed along the side surface L2_W of the second layer L2 and may be in contact with the side surface L2_W of the second layer L2. That is, the side surface of the connecting line CN may be exposed by the first through hole OP-P and the second through hole OP-60, and the connecting electrode CNE may be in contact with the exposed side surface of the connecting line CN (that is, the side surface L2_W of the second layer L2).

As described herein, the second electrode EL2 may be in contact with the connecting electrode CNE through the second contact area CAb. The second contact area CAb may be provided adjacent to the side surface L2_W of the second layer L2 exposed from the sixth insulating layer 60 and the pixel defining layer PDL by the first through hole OP-P and the second through hole OP-60. In the second contact area CAb, the end portion EN1 of the second electrode EL2 may be in contact with the end portion CEN1 of the connecting electrode CNE that is in contact with the side surface L2_W of the second layer L2. Specifically, through a difference in deposition angle between the second electrode EL2 and the intermediate layer IML, the second electrode EL2 may be in contact with the end portion CEN1 of the connecting line CN exposed from the intermediate layer IML by the tip portion TIP. That is, without a separate patterning process for the intermediate layer IML, the second electrode EL2 may be connected to the connecting electrode CNE and may be connected to the connecting line CN through the connecting electrode CNE. Accordingly, the light emitting element LD may be electrically connected with the pixel driver PDC through the connecting line CN.

In this embodiment, the connection area CNA may include a first connection area CNAa and a second connection area CNAb. The first connection area CNAa may be defined as an area where the connecting electrode CNE is connected to the third layer L3 of the connecting line CN exposed by the first through hole OP-P and the second through hole OP-60. The second connection area CNAb may be defined as an area where the connecting electrode CNE is connected to the first layer Li and the second layer L2 of the connecting line CN exposed by the first through hole OP-P and the second through hole OP-60. That is, the second connection area CNAb may correspond to an area where the connecting electrode CNE is partially disconnected by the tip portion TIP and, under the tip portion TIP, connected to the edge of the connecting line CN where the tip portion TIP is defined.

According to this embodiment, the connecting electrode CNE may be brought into contact with not only the upper surface of the connecting line CN but also the side surface of the connecting line CN, and thus the contact reliability between the connecting electrode CNE and the connecting line CN may be further improved. In some aspects, since the tip portion TIP is defined on the connecting line CN, the cathode EL2 may be in contact with the end portion of the connecting electrode CNE brought into contact with the side surface of the connecting line CN. Accordingly, the cathode EL2 may be brought into contact with the connecting electrode CNE not only in the area adjacent to the separator SPR but also in the area adjacent to the tip portion TIP of the connecting line CN, and thus the contact reliability between the connecting electrode CNE and the cathode EL2 may be further improved. As a result, a relatively high luminance may be maintained even with a lower drive voltage such that a low margin for the drive voltage may be implemented and power consumption may be reduced. That is, for example, embodiments of the present disclosure support maintaining a relatively high luminance even with a lower drive voltage, such that a display device DD (and electronic device including the display device DD) may be implemented with a low margin for the drive voltage and power consumption may be reduced. In some aspects, relatively high contact reliability may be maintained even in a high-temperature and high-humidity environment.

In FIGS. 5 and 7, the opposite end portion CEN2 of the connecting electrode CNE, the opposite end portion IN2 of the intermediate layer IML, and the opposite end portion EN2 of the second electrode EL2 are illustrated as covering the side surface L3_W of the third layer L3. However, this is illustrative, and at least a portion of the side surface L3_W of the third layer L3 may be exposed from the opposite end portion CEN2 of the connecting electrode CNE, the opposite end portion IN2 of the intermediate layer IML, and the opposite end portion EN2 of the second electrode EL2.

Referring again to FIG. 5, the encapsulation layer ECL may be disposed on the light emitting element layer LDL. The encapsulation layer ECL may cover the light emitting element LD and may cover the separator SPR. The encapsulation layer ECL may include a first inorganic layer IL1, an organic layer OL, and a second inorganic layer IL2 sequentially stacked one above another. However, without being limited thereto, the encapsulation layer ECL may further include a plurality of inorganic layers and a plurality of organic layers. In some aspects, the encapsulation layer ECL may be a glass substrate.

The first inorganic layer IL1 and the second inorganic layer IL2 may protect the light emitting element LD from moisture and oxygen outside the display panel DP, and the organic layer OL may protect the light emitting element LD from foreign matter such as, for example, particles remaining in the process of forming the first inorganic layer IL1. The first inorganic layer IL1 and the second inorganic layer IL2 may include a silicon nitride layer, a silicon oxy nitride layer, a silicon oxide layer, a titanium oxide layer, or an aluminum oxide layer. The organic layer OL may include an acrylic organic layer, but is not limited thereto.

The sensing layer ISL may sense an external input. In this embodiment, the sensing layer ISL may be formed on the encapsulation layer ECL through a continuous process. In this case, the sensing layer ISL may be expressed as being directly disposed on the encapsulation layer ECL. The expression “directly disposed” used herein may mean that another component is not disposed between the sensing layer ISL and the encapsulation layer ECL. That is, a separate adhesive member may not be disposed between the sensing layer ISL and the encapsulation layer ECL. However, this is illustrative, and in the display panel DP according to an embodiment of the present disclosure, the sensing layer ISL may be separately formed and then coupled with the display panel DP through an adhesive member and is not limited to any one embodiment.

The sensing layer ISL may include a plurality of conductive layers and a plurality of insulating layers. The plurality of conductive layers may include a first sensing conductive layer MTL1 and a second sensing conductive layer MTL2, and the plurality of insulating layers may include first to third sensing insulation layers 71, 72, and 73. However, this is illustrative, and the number of conductive layers and the number of insulating layers are not limited to any one embodiment.

Each of the first to third sensing insulation layers 71, 72, and 73 may have a single-layer structure or may have a multilayer structure stacked in the third direction DR3. The first to third sensing insulation layers 71, 72, and 73 may include an inorganic film. The inorganic film may include at least one of aluminum oxide, titanium oxide, silicon oxide, silicon nitride, silicon oxy nitride, zirconium oxide, and hafnium oxide. The first to third sensing insulation layers 71, 72, and 73 may include an organic film. The organic film may include at least one of an acrylic resin, a methacrylic resin, a polyisoprene resin, a vinyl resin, an epoxy resin, a urethane-based resin, a cellulosic resin, a siloxane-based resin, a polyimide resin, a polyamide resin, and a perylene-based resin.

The first sensing conductive layer MTL1 may be disposed between the first sensing insulation layer 71 and the second sensing insulation layer 72, and the second sensing conductive layer MTL2 may be disposed between the second sensing insulation layer 72 and the third sensing insulation layer 73. A portion of the second sensing conductive layer MTL2 may be connected with the first sensing conductive layer MTL1 through a contact hole CNT formed in the second sensing insulation layer 72. Each of the first sensing conductive layer MTL1 and the second sensing conductive layer MTL2 may have a single-layer structure or may have a multilayer structure stacked in the third direction DR3.

A sensing conductive layer having a single-layer structure may include a metal layer or a transparent conductive layer. The metal layer may include molybdenum, silver, titanium, copper, aluminum, or an alloy thereof. The transparent conductive layer may include transparent conductive oxide such as, for example, indium tin oxide (ITO), indium zinc oxide (IZO), zinc oxide (ZnO), indium zinc tin oxide (IZTO), or the like. Alternatively, the transparent conductive layer may include a conductive polymer such as, for example, PEDOT, a metal nano-wire, or graphene.

A sensing conductive layer having a multilayer structure may include metal layers. The meal layers may have, for example, a three-layer structure of titanium (Ti)/aluminum (Al)/titanium (Ti). Alternatively, the multilayered sensing conductive layer may include at least one metal layer and at least one transparent conductive layer.

In the sensing layer ISL, the first sensing conductive layer MTL1 and the second sensing conductive layer MTL2 may constitute a sensor that senses an external input. The sensor may be driven in a capacitance type. The sensor may be driven in a mutual-cap type or a self-cap type. However, this is illustrative, and the sensor may be driven in a resistive type, an ultrasonic type, or an infrared type in addition to the capacitance type and is not limited to any one embodiment.

Each of the first sensing conductive layer MTL1 and the second sensing conductive layer MTL2 may include transparent conductive oxide and may have a metal mesh shape formed of an opaque conductive material. As long as the visibility of an image displayed by the display panel DP is not deteriorated, the first sensing conductive layer MTL1 and the second sensing conductive layer MTL2 may have various materials and shapes and are not limited to any one embodiment.

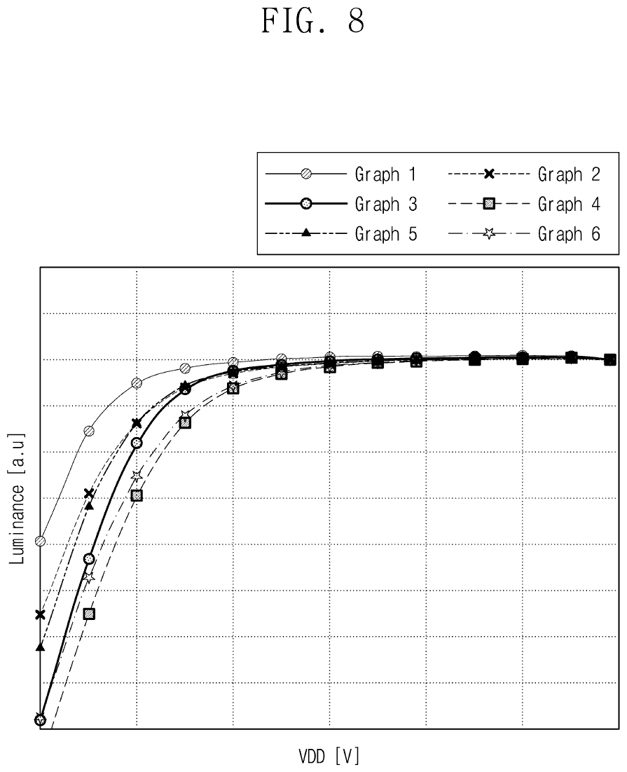

FIG. 8 is a graph depicting luminance versus first power supply voltage VDD in an embodiment of the present disclosure and a comparative example. In describing FIG. 8, a display panel of the embodiment of the present disclosure has a structure corresponding to FIG. 5. In describing FIG. 8, a display panel of the comparative example has a structure in which a side portion of a connecting line is not exposed from an insulating layer and a pixel defining layer and a tip portion is not defined on the connecting line.

Graph 1 is a graph for a light emitting element that provides red light in the embodiment of the present disclosure, and Graph 2 is a graph for a light emitting element that provides red light in the comparative example. Graph 3 is a graph for a light emitting element that provides green light in the embodiment of the present disclosure, and Graph 4 is a graph for a light emitting element that provides green light in the comparative example. Graph 5 is a graph for a light emitting element that provides blue light in the embodiment of the present disclosure, and Graph 6 is a graph for a light emitting element that provides blue light in the comparative example.

Referring to FIGS. 1, 5, and 8, the luminance of light provided through the light emitting element LD is decreased as the first power supply voltage VDD is lowered. Referring to Graph 1 and Graph 2, it can be seen that in the case of the light emitting element LD that provides red light, according to the embodiment of the present disclosure, the rate at which the luminance of light decreases as the first power supply voltage VDD decreases is lower than that in the comparative example. Referring to Graph 3 and Graph 4, it can be seen that even in the case of the light emitting element LD that provides green light, according to the embodiment of the present disclosure, the rate at which the luminance of light decreases as the first power supply voltage VDD decreases is lower than that in the comparative example. Referring to Graph 5 and Graph 6, it can be seen that even in the case of the light emitting element LD that provides blue light, according to the embodiment of the present disclosure, the rate at which the luminance of light decreases as the first power supply voltage VDD decreases is lower than that in the comparative example. That is, according to the embodiment of the present disclosure, it can be seen that relatively high luminance is maintained even with a relatively low first power supply voltage VDD for all of red light, green light, and blue light. Accordingly, according to the embodiment of the present disclosure, a margin for the first power supply voltage VDD may be lower than the margin relied on in the comparative example, and thus power consumption may be reduced.

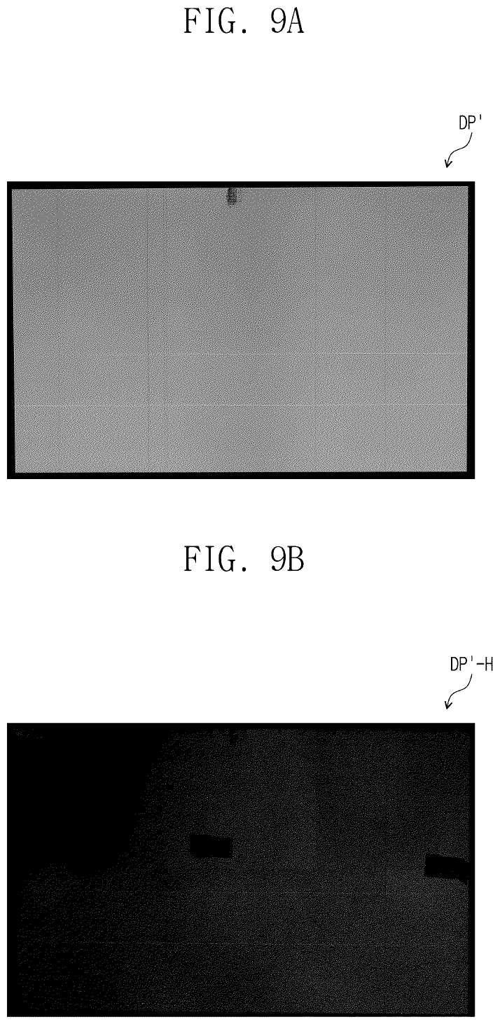

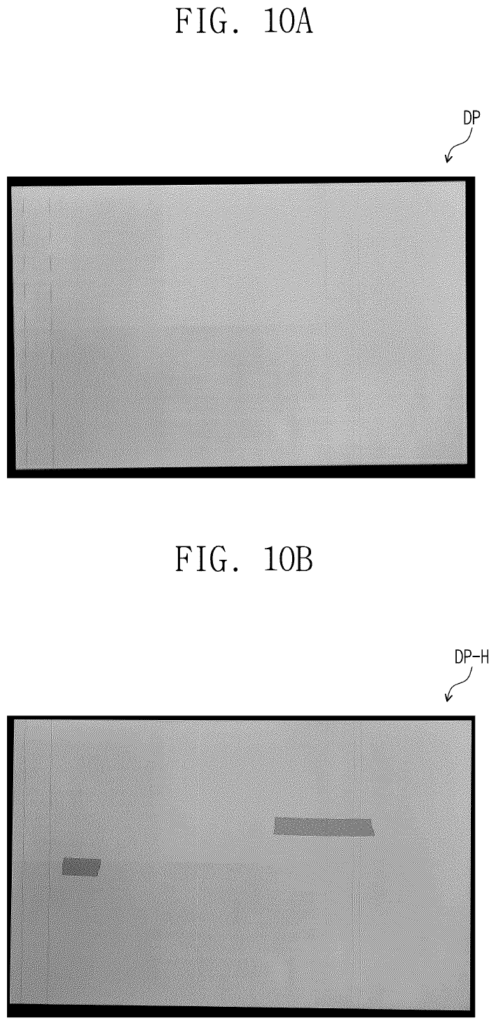

FIGS. 9A and 9B illustrate images related to UHAST evaluation according to a comparative example. FIGS. 10A and 10B illustrate images related to UHAST evaluation according to an embodiment of the present disclosure. Display panels DP′ and DP′-H used in the UHAST evaluation of FIGS. 9A and 9B have a structure in which a side portion of a connecting line is not exposed from an insulating layer and a pixel defining layer and a tip portion is not defined on the connecting line. Display panels DP and DP-H used in the UHAST evaluation of FIGS. 10A and 10B have a structure corresponding to FIG. 5.

The UHAST evaluations in FIGS. 9A to 10B were performed at the temperature of 85° C. and the humidity of 85%. FIGS. 9A and 10A illustrate images illustrating the screens of the display panels DP′ and DP before the UHAST evaluations, and FIGS. 9B and 10B illustrate images illustrating the screens of the display panels DP′-H and DP-H after the display panels DP′-H and DP-H were exposed to the temperature condition of 85° C. and the humidity condition of 85% for 240 hours.

First, referring to FIGS. 9A and 9B, in the case of the comparative example, it can be seen that stains appear on the screens with a decrease in luminance when the display panels are exposed to high temperature and high humidity conditions. That is, in the case of the comparative example, it can be seen that when the display panels are exposed to high temperature and high humidity conditions, luminance provided through a light emitting element is decreased as contact reliability is lowered.

In contrast, referring to FIGS. 10A and 10B, in the case of the embodiment of the present disclosure, it can be seen that even though the display panels are exposed to high temperature and high humidity conditions, the luminance is maintained at a similar level and there are no stains on the screens. That is, in the case of the embodiment of the present disclosure, it can be seen that even though the display panels are exposed to high temperature and high humidity conditions, contact reliability is maintained such that a decrease in luminance provided through a light emitting element is prevented or the degree of decrease in luminance is reduced.

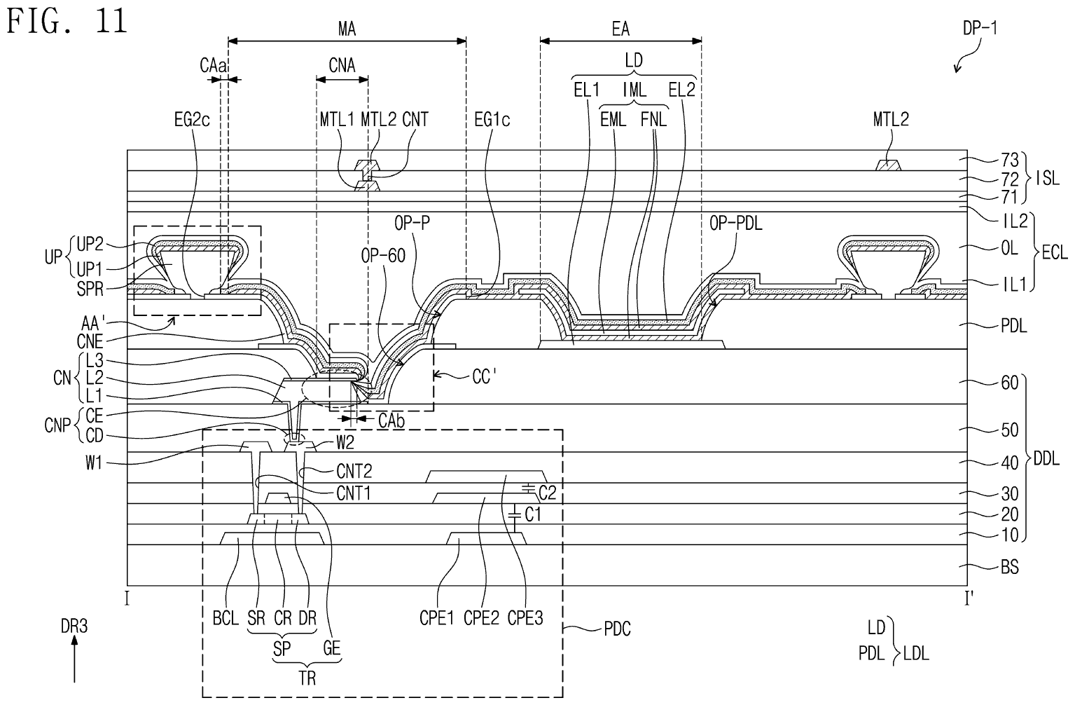

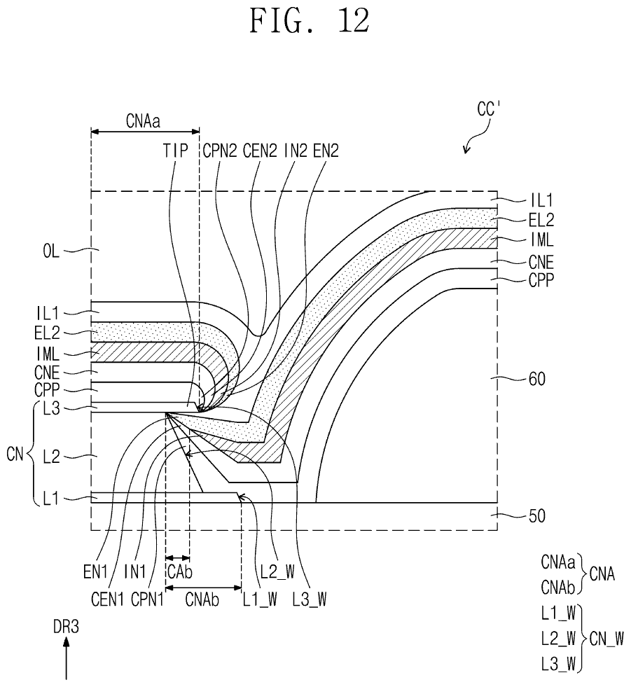

FIG. 11 is a sectional view of a display panel DP-1 according to an embodiment of the present disclosure. FIG. 12 is an enlarged sectional view of a partial area of the display panel DP-1 according to an embodiment of the present disclosure. FIG. 12 illustrates an enlarged sectional view of area CC′ of FIG. 11. Components identical or similar to the components described with reference to FIGS. 5 to 7 will be assigned with the identical or similar reference numerals, and repetitive descriptions will be omitted.

Referring to FIGS. 11 and 12, when compared to the display panel DP illustrated in FIG. 5, the display panel DP-1 of an embodiment may further include a capping pattern CPP. The capping pattern CPP may be disposed on the sixth insulating layer 60. In some aspects, the capping pattern CPP may also be disposed on a partial area of the connecting line CN exposed by the second through hole OP-60 of the sixth insulating layer 60. The capping pattern CPP may be disposed to overlap the connecting line CN. Specifically, the capping pattern CPP may be disposed to overlap the light emitting connection part CE and/or the tip portion TIP.

In some aspects, as illustrated in FIGS. 11 and 12, the capping pattern CPP, when viewed on the cross-section, may have a shape that is partially disconnected with respect to the tip portion TIP in the area where the light emitting connection part CE is defined. However, when viewed from above the plane, the capping pattern CPP may have a one-body shape that is connected as a whole within the area (refer to FIG. 4) defined as a closed line by the separator SPR. In some aspects, an end portion CPN1 of the partially disconnected capping pattern CPP may be in contact with the side surface L2_W of the second layer L2 of the connecting line CN, and another end portion CPN2 of the capping pattern CPP may be disposed on the third layer L3 of the connecting line CN and may cover the tip portion TIP.

The capping pattern CPP may include a conductive material. Accordingly, the connecting electrode CNE and the second electrode EL2 may be electrically connected to the connecting line CN through the capping pattern CPP. That is, the capping pattern CPP may be in contact with the side surface L2_W of the second layer L2 of the connecting line CN, the connecting electrode CNE may be in contact with the capping pattern CPP, and the second electrode EL2 may be in contact with the connecting electrode CNE. Accordingly, all of them may be electrically connected. The capping pattern CPP may be disposed outward of the second layer L2 of the connecting line CN, and the connecting electrode CNE may be electrically connected with the second layer L2 by being connected to the capping pattern CPP instead of the side surface L2_W of the second layer L2. Accordingly, the connection between the connecting line CN and the connecting electrode CNE may be more easily performed, and thus the connection between the second electrode EL2 and the connecting line CN may also be more easily performed.

In an embodiment of the present disclosure, the capping pattern CPP may include a material having a lower reactivity than the second layer L2 of the connecting line CN. For example, the capping pattern CPP may include copper (Cu), silver (Ag), or transparent conductive oxide. The side surface L2_W of the second layer L2 of the connecting line CN may be protected by the capping pattern CPP having a lower reactivity than the second layer L2 of the connecting line CN, and thus oxidation of the material included in the second layer L2 may be prevented. In some aspects, a phenomenon in which a silver (Ag) component contained in the first electrode EL1 is reduced during an etching process of making the first electrode EL1 subject to patterning and remains as particles causing defects may be prevented.

In an embodiment, the capping pattern CPP may be formed through the same process as the first electrode EL1 and may include the same material as the first electrode EL1. However, this is illustrative, and the capping pattern CPP may be formed through a process different from the process used for forming the first electrode EL1 and may include a material different from a material of the first electrode EL1. The present disclosure is not limited to any one embodiment.

As described herein, the light emitting element and the pixel driver may be stably brought into contact with each other, and thus the contact reliability may be improved.

In the electronic device according to the embodiment, the connecting electrode electrically connected with the pixel driver and the cathode of the light emitting element may be brought into contact with each other in the area adjacent to the separator provided for separation of the pixels. Accordingly, the connecting electrode and the cathode of the light emitting element may be connected in a relatively wide area, and thus the contact reliability may be improved. The connecting electrode and the pixel driver may be electrically connected through the connecting line.

In the electronic device according to the embodiment, the connecting electrode may be brought into contact with not only the upper surface of the connecting line but also the side surface of the connecting line, and thus the contact reliability between the connecting electrode and the connecting line may be further improved. In some aspects, the tip portion may be defined on the connecting line, and thus the cathode may be in contact with the end portion of the connecting electrode brought into contact with the side surface of the connecting line. Accordingly, the cathode may be brought into contact with the connecting electrode not only in the area adjacent to the separator but also in the area adjacent to the tip portion of the connecting line, and the contact reliability between the connecting electrode and the cathode may be further improved.

As a result, a relatively high luminance may be maintained even with a lower drive voltage such that a low margin for the drive voltage may be implemented and power consumption may be reduced. That is, for example, embodiments of the present disclosure support implementing a display device (and electronic device including the display device) with a low margin for the drive voltage, which may support reduced power consumption. In some aspects, relatively high contact reliability may be maintained even in a high-temperature and high-humidity environment.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a drive element layer comprising a pixel driver;
a light emitting element disposed on the drive element layer, the light emitting element comprising a first electrode, an intermediate layer disposed on the first electrode and comprising at least an emissive layer, and a second electrode disposed on the intermediate layer;
a pixel defining layer disposed on the drive element layer, wherein an opening defined in the pixel defining layer exposes at least a portion of the first electrode;
a connecting electrode disposed on the pixel defining layer and electrically connected with the pixel driver and the second electrode;
a connecting line disposed between the pixel driver and the pixel defining layer and electrically connected with the pixel driver and the connecting electrode; and
a separator disposed on the pixel defining layer,
wherein the second electrode is in contact with the connecting electrode in each of a first contact area adjacent to the separator and a second contact area adjacent to a side surface of the connecting line.

2. The electronic device of claim 1, wherein a lower surface of the second electrode is in contact with an upper surface of the connecting electrode in the first contact area.

3. The electronic device of claim 1, wherein:
a tip portion is defined on at least a portion of an edge of the connecting line, and
the second contact area is adjacent to the tip portion.

4. The electronic device of claim 3, wherein:
the connecting line comprises a first layer, a second layer disposed on the first layer, and a third layer disposed on the second layer, and
a side surface of each of the first layer and the third layer protrudes relative to a side surface of the second layer.

5. The electronic device of claim 4, wherein:
an end portion of the connecting electrode is connected to the side surface of the second layer, and
an end portion of the second electrode is in contact with the end portion of the connecting electrode connected to the side surface of the second layer.

6. The electronic device of claim 5, wherein each of an opposite end portion of the connecting electrode and an opposite end portion of the second electrode is disposed on an upper surface of the first layer.

7. The electronic device of claim 6, wherein the end portion of the connecting electrode is in contact with the side surface of the second layer.

8. The electronic device of claim 6, further comprising:
a capping pattern disposed between the connecting line and the connecting electrode,
wherein:
an end portion of the capping pattern is in contact with the side surface of the second layer, and an opposite end portion of the capping pattern is disposed on the upper surface of the first layer, and
the end portion of the second electrode is in contact with the end portion of the capping pattern brought into contact with the side surface of the second layer.

9. The electronic device of claim 3, wherein a first through hole defined in the pixel defining layer exposes the tip portion defined on at least the portion of the edge of the connecting line.

10. The electronic device of claim 9, wherein:
the drive element layer further comprises an intermediate insulating layer disposed under the pixel defining layer and covering a portion of the connecting line, and
a second through hole defined in the intermediate insulating layer exposes the tip portion defined on at least the portion of the edge of the connecting line.

11. The electronic device of claim 1, wherein:
the drive element layer further comprises a lower insulating layer disposed between the pixel driver and the connecting line, and
the connecting line is connected to the pixel driver through a contact hole penetrating the lower insulating layer.

12. The electronic device of claim 1, wherein:
the connecting electrode has a ring shape and surrounds the opening, and
the first contact area has a ring shape and surrounds at least a portion of the opening.

13. The electronic device of claim 1, wherein:
the connecting electrode comprises a first edge and a second edge surrounding the first edge, and
the second edge overlaps the separator.

14. The electronic device of claim 1, wherein a portion of the connecting electrode is covered by the separator.

15. The electronic device of claim 1, wherein:
the light emitting element comprises a plurality of light emitting elements, the pixel driver comprises a plurality of pixel drivers, and the connecting electrode comprises a plurality of connecting electrodes,
the plurality of connecting electrodes electrically connect the plurality of light emitting elements and the plurality of pixel drivers, respectively, and
a gap between connecting electrodes adjacent to each other among the plurality of connecting electrodes overlaps the separator.

16. The electronic device of claim 1, wherein:
the intermediate layer further comprises a functional layer,
the functional layer comprises a first intermediate functional layer disposed on the first electrode and a second intermediate functional layer disposed on the emissive layer, and
the emissive layer is disposed between the first intermediate functional layer and the second intermediate functional layer.

17. The electronic device of claim 16, further comprising:
a first dummy layer disposed on the separator, the first dummy layer comprising a same material as the functional layer; and
a second dummy layer disposed on the first dummy layer, the second dummy layer comprising a same material as the second electrode.

18. An electronic device comprising:
a drive element layer comprising a pixel driver;
a light emitting element disposed on the drive element layer, the light emitting element comprising a first electrode, an intermediate layer disposed on the first electrode and comprising at least an emissive layer, and a second electrode disposed on the intermediate layer;
a pixel defining layer disposed on the drive element layer, wherein an opening defined in the pixel defining layer exposes at least a portion of the first electrode;
a connecting electrode disposed on the pixel defining layer and electrically connected with the pixel driver and the second electrode;
a connecting line disposed between the pixel driver and the pixel defining layer and electrically connected with the pixel driver and the connecting electrode; and
a separator disposed on the pixel defining layer,
wherein:
an edge of the connecting electrode overlaps the separator,
a tip portion is defined on at least a portion of an edge of the connecting line, and
the connecting electrode is connected to at least the portion of the edge of the connecting line where the tip portion is defined.

19. The electronic device of claim 18, wherein the second electrode is in contact with the connecting electrode in each of a first contact area adjacent to the separator and a second contact area adjacent to the tip portion of the connecting line.

20. The electronic device of claim 18, wherein:
the connecting line comprises a first layer, a second layer disposed on the first layer, and a third layer disposed on the second layer,
a side surface of each of the first layer and the third layer protrudes relative to a side surface of the second layer,
an end portion of the connecting electrode is connected to the side surface of the second layer, and
an end portion of the second electrode is in contact with the end portion of the connecting electrode connected to the side surface of the second layer.
